(19) United States
(12) Patent Application Publication
(10) Pub. No.: US 2026/0129757 A1
(43) Pub. Date: May 7, 2026

(54) WIRING SUBSTRATE

(71) Applicant: Shinko Electric Industries Co., Ltd., Nagano-shi (JP)

(72) Inventors: Yuki Kobayashi, Nagano-shi (JP); Takashi Nishiyama, Nagano-shi (JP); Masaya Takizawa, Nagano-shi (JP)

(73) Assignee: Shinko Electric Industries Co., Ltd., Nagano-shi (JP)

(21) Appl. No.: 19/372,871

(22) Filed: Oct. 29, 2025

(30) Foreign Application Priority Data
Nov. 1, 2024 (JP) 2024-192684
Mar. 17, 2025 (JP) 2025-042327

(51) Int. Cl. H05K 1/11; H05K 3/00

(52) U.S. Cl. CPC H05K 1/116; H05K 3/0026; H05K 3/0094; H05K 2201/0338; H05K 2201/09481; H05K 2201/09527; H05K 2201/09618

(57) ABSTRACT

A wiring substrate includes an insulation layer covering a wiring layer, a via hole in the insulation layer, a via wiring filling the via hole, and a wiring layer formed on the insulation layer. The wiring layer includes a metal layer and an adhesion layer formed the metal layer. The adhesion layer includes a wall cover covering a wall surface of at least a lower part of the via hole. The via wiring includes the wall cover, an adhesion layer formed on a wall surface of the via hole to cover an inner surface of the wall cover, a metal film covering the adhesion layer, and a metal layer filling the via hole on an inner side of the metal film. The adhesion layer covering an upper surface of the metal layer is greater in thickness than the adhesion layer covering an upper surface of the insulation layer.

### CROSS-REFERENCE TO RELATED APPLICATIONS

This application is based upon and claims the benefit of priority from Japanese Patent Applications No. 2024-192684, filed on Nov. 1, 2024 and No. 2025-042327, filed on Mar. 17, 2025, the entire contents of which are incorporated herein by reference.

### BACKGROUND

### 1. Field

This disclosure relates to a wiring substrate and a method for manufacturing a wiring substrate.

### 2. Description of Related Art

Wiring substrates on which electronic components such as semiconductor elements are mounted have various shapes and various structures. JP2021-168348A discloses an example of such a wiring substrate formed by a build-up process that alternately stacks wiring layers and insulation layers. The wiring layers are electrically connected to each other by via wirings that are formed in through holes extending through the insulation layers in a thickness-wise direction.

### SUMMARY

It is desirable that the electrical connection reliability of the above-described wiring substrate be improved.

In an aspect of the present disclosure, a wiring substrate includes a first wiring layer, a first insulation layer covering an upper surface and a side surface of the first wiring layer, a via hole extending through the first insulation layer in a thickness-wise direction and exposing a portion of the upper surface of the first wiring layer, a via wiring filling the via hole, and a second wiring layer formed integrally with the via wiring and stacked on an upper surface of the first insulation layer. The first wiring layer includes a first metal layer and a first adhesion layer formed on an upper surface of the first metal layer. The first adhesion layer includes a wall cover covering a wall surface of at least a lower part of the via hole. The via wiring includes the wall cover, a second adhesion layer formed on a wall surface of the via hole so as to cover an inner surface of the wall cover, a first metal film covering the second adhesion layer, and a second metal layer filling the via hole on an inner side of the first metal film. The second adhesion layer covers the upper surface of the first insulation layer. A portion of the first adhesion layer that covers the upper surface of the first metal layer is greater in thickness than a portion of the second adhesion layer that covers the upper surface of the first insulation layer.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic cross-sectional view illustrating a wiring substrate in accordance with some embodiment.

FIG. 2 is a schematic cross-sectional view illustrating, in an enlarged manner, part of the wiring substrate in accordance with a first embodiment.

FIGS. 3, 4, 5, 6, 7, 8, 9, 10, 11, 12, 13, 14, 15, 16, and 17 are schematic cross-sectional views illustrating a method for manufacturing the wiring substrate of FIG. 2.

FIG. 18 is a schematic cross-sectional view illustrating a structure of a sample used in a test.

FIGS. 19A and 19B are graphs illustrating test results.

FIG. 20 is a schematic cross-sectional view illustrating, in an enlarged manner, part of a wiring substrate in accordance with a second embodiment.

FIGS. 21, 22, 23, 24, and 25 are schematic cross-sectional views illustrating a method for manufacturing the wiring substrate of FIG. 20.

FIGS. 26, 27, and 28 are schematic cross-sectional views illustrating wiring substrates of various modified examples.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments will be described below with reference to the accompanying drawings.

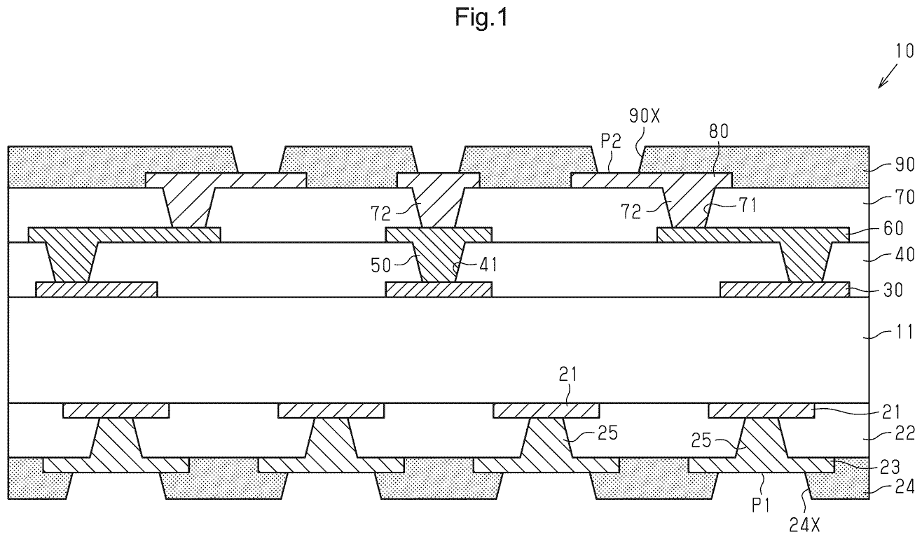

Elements in the drawings may be partially enlarged for simplicity and clarity and thus have not necessarily been drawn to scale. To facilitate understanding, hatching lines may not be illustrated or may be replaced by shadings in the cross-sectional drawings. In this specification, a plan view refers to a view of a subject taken in a vertical direction (e.g., vertical direction as viewed in FIG. 1), and a planar shape refers to a shape of a subject as viewed in the vertical direction. In this specification, the frame of reference for “the vertical direction” and “the sideward direction” is each drawing positioned so that the reference characters are properly read. In the description of the present disclosure, a numerical range of “X1 to X2,” which is specified by the lower limit value X1 and the upper limit value X2,refers to a range that is greater than or equal to X1 and less than or equal to X2, unless otherwise specified.

### FIRST EMBODIMENT

A first embodiment will now be described with reference to FIGS. 1 to 17.

### General Structure of Wiring Substrate 10

As illustrated in FIG. 1, a wiring substrate 10 includes a substrate body 11. A wiring layer 21, an insulation layer 22, a wiring layer 23, and a solder resist layer 24 are sequentially stacked on the lower surface of the substrate body 11. A wiring layer 30, an insulation layer 40, a wiring layer 60, an insulation layer 70, a wiring layer 80, and a solder resist layer 90 are sequentially stacked on the upper surface of the substrate body 11.

The substrate body 11 may be, for example, a wiring structural body in which insulating resin layers and wiring layers are alternately stacked. In an example, the wiring structural body may, but does not necessarily have to, include a core substrate. The material of the insulating resin layer may be, for example, a thermosetting insulating resin. The thermosetting insulating resin may be an epoxy resin, a polyimide resin, or a cyanate resin. The insulating resin layer may include, for example, a filler such as silica or alumina. The substrate body 11 may be, for example, a core substrate including a through-electrode.

The material of a wiring layer in the substrate body 11 and the wiring layers 21, 23, 30, 60, and 80 may be, for example, copper (Cu) or a copper alloy. The thickness of the wiring layers 21, 23, 30, 60, and 80 may be, for example, approximately 5 μm to 20 μm. The material of the insulation layers 22, 40, and 70 may be, for example, a thermosetting insulating resin. The thermosetting insulating resin may be an epoxy resin, a polyimide resin, or a cyanate resin. Also, the material of the insulation layers 22, 40, and 70 may be, for example, an insulating resin including a photosensitive resin such as a phenol resin or a polyimide resin as a main component. The insulation layers 22, 40, and 70 may include, for example, a filler such as silica or alumina. The material of the solder resist layers 24 and 90 may be, for example, an insulating resin including a photosensitive resin such as a phenol resin or a polyimide resin as a main component. The solder resist layers 24 and 90 may include, for example, a filler such as silica or alumina.

The wiring layer 21 is formed on the lower surface of the substrate body 11. The insulation layer 22 is formed on the lower surface of the substrate body 11 to cover the wiring layer 21. The wiring layer 23 is formed on the lower surface of the insulation layer 22. The wiring layer 23 is electrically connected to the wiring layer 21 by via wirings 25 extending through the insulation layer 22 in the thickness-wise direction. In an example, the wiring layer 23 is formed continuously and integrally with the via wirings 25.

The solder resist layer 24 is formed on the lower surface of the insulation layer 22 to cover the wiring layer 23. The solder resist layer 24 is the outermost (in this example, lowermost) insulation layer of the wiring substrate 10.

The solder resist layer 24 includes a plurality of openings 24X formed to expose parts of a lower surface of the wiring layer 23 as external connection pads P1. The external connection pads P1 are connected to external connection terminals (not illustrated) used when mounting the wiring substrate 10 on a mount substrate such as a motherboard.

A surface-processed layer may be formed on the lower surface of the wiring layer 23 exposed in the bottom of the openings 24X. In an example, the surface-processed layer includes a gold (Au) layer, a nickel (Ni) layer/Au layer (metal layer in which the Ni layer serves as bottom layer and the Au layer is stacked on the Ni layer), and a Ni layer/palladium (Pd) layer/Au layer (metal layer in which the Ni layer serves as bottom layer and the Ni layer, the Pd layer, and the Au layer are stacked in this order). In an example, the surface-processed layer includes a Ni layer/Pd layer (metal layer in which the Ni layer serves as bottom layer and the Pd layer is stacked on the Ni layer), a Pd layer/Au layer (metal layer in which the Pd layer serves as bottom layer and the Au layer is stacked on the Pd layer), or the like. The Au layer is a metal layer of Au or a Au alloy. The Ni layer is a metal layer of Ni or a Ni alloy. The Pd layer is a metal layer of Pd or a Pd alloy. Each of the Au layer, the Ni layer, and the Pd layer may be, for example, a metal layer (electroless plated layer) formed through an electroless plating process or a metal layer (electrolytic plated layer) formed through an electrolytic plating process. Alternatively, the surface-processed layer may be an organic solderability preservative (OPS) film formed by performing an oxidation-resisting process, such as an OSP process, on the lower surface of the wiring layer 23 exposed at the bottom of the openings 24X. The OSP film may be a coating of an organic compound such as an azole compound or an imidazole compound. When a surface-processed layer is formed on the lower surface of the wiring layer 23, the surface-processed layer is used as the external connection pads P1.

In the present example, external connection terminals are arranged on the lower surface of the wiring layer 23. Instead, the wiring layer 23 exposed at the bottom of the openings 24X may be used as the external connection terminals. Alternatively, when a surface-processed layer is formed on the lower surface of the wiring layer 23, the surface-processed layer may be used as the external connection terminals.

The wiring layer 30 is formed on the upper surface of the substrate body 11. The wiring layer 30 is electrically connected to the wiring layer 21 through, for example, wiring layers and through-electrodes in the substrate body 11.

The insulation layer 40 is formed on the upper surface of the substrate body 11 to cover the wiring layer 30. The insulation layer 40 has via holes 41 extending through the insulation layer 40 in the thickness-wise direction to expose portions of the upper surface of the wiring layer 30. The thickness from the upper surface of the wiring layer 30 to the upper surface of the insulation layer 40 may be, for example, approximately 10 μm to 30 μm.

The wiring layer 60 is formed on the upper surface of the insulation layer 40. Via wirings 50 are formed in the via holes 41 to electrically connect the wiring layer 60 to the wiring layer 30. The wiring layer 60 is formed continuously and integrally with the via wirings 50. In an example, the via wirings 50 fill the via holes 41.

The insulation layer 70 is formed on the upper surface of the insulation layer 40 to cover the wiring layer 60. The insulation layer 70 has via holes 71 extending through the insulation layer 70 in the thickness-wise direction to expose portions of the upper surface of the wiring layer 60. The thickness from the upper surface of the wiring layer 60 to the upper surface of the insulation layer 70 may be, for example, approximately 10 μm to 30 μm.

The via holes 41 and 71 may have any planar shape and any planar size. In the present example, the via holes 41 and 71 are each circular in plan view. Each of the via holes 41 and 71 is, for example, tapered and has a diameter (opening width) that decreases from the upper side (side close to the solder resist layer 90) toward the lower side (side closer to the substrate body 11) in FIG. 1. The via holes 41 and 71 each have the shape of an inverted truncated cone such that the lower open end has a smaller diameter than the upper open end. The wall surface of each of the via holes 41 and 71 is, for example, inclined toward the center of the via holes 41 and 71 in plan view as the wall surface extends from the upper side toward the lower side in FIG. 1. The wall surface of each of the via holes 41 and 71 does not have to be straight. The wall surface of each of the via holes 41 and 71 may be partially or entirely convex or concave. In the present example, the wall surface of each of the via holes 41 and 71 is inclined at a constant inclination angle. The depth of the via holes 41 and 71 may be, for example, approximately 10 μm to 30 μm. The diameter of each of the via holes 41 and 71 may be, for example, approximately 10 μm to 50 μm.

The wiring layer 80 is formed on the upper surface of the insulation layer 70. The wiring layer 80 is the outermost (in this example, uppermost) wiring layer of the wiring substrate 10. In an example, via wirings 72 are formed in the via holes 71 to electrically connect the wiring layer 80 to the wiring layer 60. In an example, the wiring layer 80 is formed continuously and integrally with the via wirings 72. In an example, the via wirings 72 fill the via holes 71.

The solder resist layer 90 is formed on the upper surface of the insulation layer 70 to cover the wiring layer 80. The solder resist layer 90 is the outermost (in this example, uppermost) insulation layer of the wiring substrate 10.

The solder resist layer 90 has a plurality of openings 90X formed to expose parts of the upper surface of the wiring layer 80 as connection pads P2. The connection pads P2 are, for example, pads for connection with an electronic component, such as a semiconductor element or the like.

A surface-processed layer is formed, if necessary, on the upper surface of the wiring layer 80 exposed at the bottom of each opening 90X. Examples of the surface-processed layer include an OSP film or a metal layer, such as an Au layer, an Ni layer/Au layer, an Ni layer/Pd layer/Au layer, an Ni layer/Pd layer, or a Pd layer/Au layer.

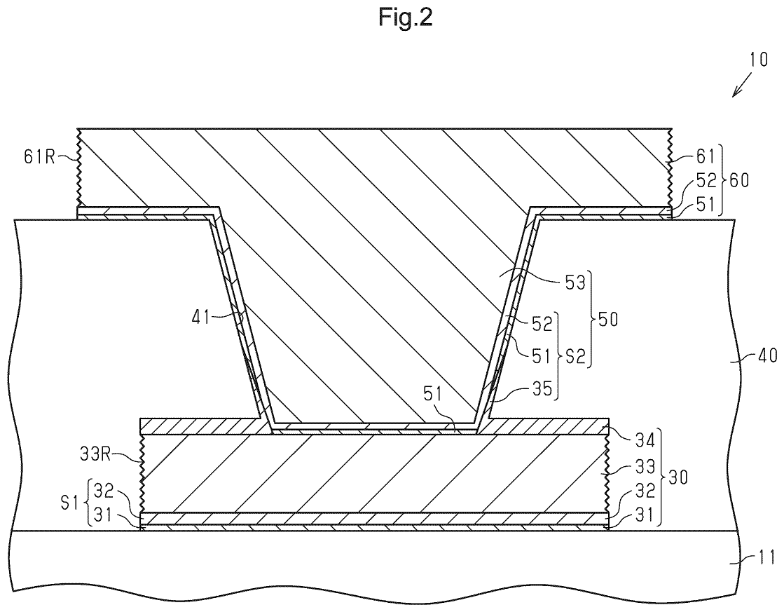

With reference to FIG. 2, the structure of the wiring layer 30, the insulation layer 40, the via holes 41, the via wirings 50, and the wiring layer 60 will now be described. In FIG. 2, the insulation layer 70, the wiring layer 80, and the solder resist layer 90 are not illustrated.

As illustrated in FIG. 2, the wiring layer 30 includes, for example, an adhesion layer 31 formed on the upper surface of the substrate body 11, a metal film 32 formed on the upper surface of the adhesion layer 31, a metal layer 33 formed on the upper surface of the metal film 32, and an adhesion layer 34 formed on the upper surface of the metal layer 33. The via wiring 50 includes, for example, an adhesion layer 51, a metal film 52, and a metal layer 53.

### Structure of the Wiring Layer 30

The adhesion layer 31 covers the upper surface of an insulating resin layer of the substrate body 11. The adhesion layer 31 is formed from a metal material having a greater adhesion to the insulating resin layer of the substrate body 11 than a metal material (e.g., copper) forming the metal film 32 and the metal layer 33. The material of the adhesion layer 31 may be, for example, titanium (Ti), titanium nitride (TiN), tantalum nitride (TaN), tantalum (Ta), nickel (Ni), or chromium (Cr). The material of the adhesion layer 31 may be, for example, a Cu-Ni alloy or a Cu-Ni-Ti alloy. In the present embodiment, the adhesion layer 31 is a Ti layer. The thickness of the adhesion layer 31 may be, for example, approximately 15 nm to 50 nm. The adhesion layer 31 may be, for example, a metal film (sputtering film) formed by sputtering.

The metal film 32 covers, for example, the entire upper surface of the adhesion layer 31. The material of the metal film 32 may be, for example, copper or a copper alloy. The thickness of the metal film 32 is, for example, greater than the thickness of the adhesion layer 31. The thickness of the metal film 32 may be, for example, approximately 100 nm to 500 nm. The metal film 32 may be, for example, a sputtering film.

The adhesion layer 31 and the metal film 32 form a seed layer S1.

The metal layer 33 covers the upper surface of the metal film 32. The material of the metal layer 33 may be, for example, copper or a copper alloy. The thickness of the metal layer 33 is, for example, greater than the thickness of the metal film 32. The thickness of the metal layer 33 may be, for example, approximately 5 μm to 20 μm. The metal layer 33 may be, for example, an electrolytic plating layer.

The side surface of the metal layer 33 includes a rough surface 33R having, for example, a greater surface roughness than the upper surface of the metal layer 33. The surface roughness of the rough surface 33R may be, for example, expressed as surface roughness Ra having a value of approximately 80 nm to 130 nm. The value of the surface roughness Ra, expressed by a numerical value indicating the surface roughness, is also referred to as arithmetic mean roughness that is the arithmetic means of measurements of vertical deviations of a surface profile from a mean line within a measurement region.

The adhesion layer 34 covers the upper surface of the metal layer 33. In an example, the adhesion layer 34 covers the entire upper surface of the metal layer 33 located at a position that does not overlap the bottom of the via hole 41 in plan view. In other words, the adhesion layer 34 covers the entire upper surface of the metal layer 33 that is not exposed at the bottom of the via hole 41. In an example, the adhesion layer 34 exposes the upper surface of the metal layer 33 that overlaps the bottom of the via hole 41 in plan view.

The adhesion layer 34 is formed from a metal material having a greater adhesion to the insulation layer 40 than a metal material (e.g., copper) forming the metal film 52 and the metal layer 53. The material of the adhesion layer 34 may be, for example, Ti, TiN, TaN, Ta, Ni, Cr, a Cu—Ni alloy, or a Cu—Ni—Ti alloy. In the present embodiment, the adhesion layer 34 is a Ti layer. The thickness of the adhesion layer 34 is greater than the thickness of the adhesion layer 31. The thickness of the adhesion layer 34 is greater than the thickness of the adhesion layer 51. The thickness of the adhesion layer 34 may be, for example, approximately 30 nm to 100 nm. The adhesion layer 34 may be, for example, a sputtering film.

The adhesion layer 34 includes a wall cover 35 covering the wall surface of at least a lower part of the via hole 41. In an example, the wall cover 35 covers the wall surface of the lower part of the via hole 41 and exposes the wall surface of an upper part of the via holes 41. In an example, the wall cover 35 is formed continuously and integrally with the portion of the adhesion layer 34 that covers the upper surface of the metal layer 33. The wall cover 35 extends upward from a lower end of the wall surface of the via hole 41. The thickness of the wall cover 35, for example, decreases from the lower end of the wall surface of the via hole 41 toward the upper surface of the insulation layer 40. The wall cover 35 includes a surface facing the inside of the via hole 41, that is, the inner surface of the wall cover 35. The inner surface of the wall cover 35 is inclined toward the center of the via hole 41 in plan view as the inner surface of the wall cover 35 extends toward the lower end of the wall surface of the via hole 41. The thickness of the wall cover 35 is smaller than the thickness of the portion of the adhesion layer 34 that covers the upper surface of the metal layer 33. In an example, the thickness of a portion of the wall cover 35 that covers the lower end of the wall surface of the via hole 41 is less than or equal to one-half of the thickness of the portion of the adhesion layer 34 that covers the upper surface of the metal layer 33. The wall cover 35 is, for example, formed by re-sputtering to re-collect a portion of the adhesion layer 34 on the wall surface of the via hole 41. Re-sputtering is also referred to as reverse sputtering.

### Structure of the Via Wiring 50

Each via wiring 50 includes, for example, the wall cover 35 of the adhesion layer 34, the adhesion layer 51 formed on the wall surface of the via hole 41 so as to cover the wall cover 35, the metal film 52 covering the adhesion layer 51, and the metal layer 53 formed in the via hole 41 on the inner side of the metal film 52.

The adhesion layer 51 covers the inner surface of the wall cover 35. In an example, the adhesion layer 51 covers a portion of the inner surface of the wall cover 35 and exposes the remaining portion of the inner surface of the wall cover 35. In the present embodiment, the adhesion layer 51 covers the inner surface of the upper end of the wall cover 35 and exposes the inner surface of the lower end of the wall cover 35. Thus, in the present embodiment, the wall cover 35, which is part of the adhesion layer 34, partially overlaps the adhesion layer 51 on the wall surface of the via hole 41.

In an example, the adhesion layer 51 covers the entire wall surface of the via hole 41 exposed from the wall cover 35. The adhesion layer 51 continuously covers the wall surface of the via hole 41 and the upper surface of the insulation layer 40. In an example, the adhesion layer 51 covers the entire upper surface of the wiring layer 30 exposed at the bottom of the via hole 41. In the present embodiment, the adhesion layer 51 covers the entire upper surface of the metal layer 33 exposed at the bottom of the via hole 41. In the present embodiment, the lower end of the wall cover 35 separates the adhesion layer 51 into a portion covering the upper surface of the metal layer 33 and a portion covering the wall cover 35.

The adhesion layer 51 is formed from a metal material having a greater adhesion to the insulation layer 40 than a metal material (e.g., copper) forming the metal film 52 and the metal layer 53. The material of the adhesion layer 51 may be, for example, Ti, TiN, TaN, Ta, Ni, Cr, a Cu—Ni alloy, or a Cu—Ni—Ti alloy. In the present embodiment, the adhesion layer 51 is a Ti layer. The thickness of the adhesion layer 51 is, for example, smaller than the thickness of the adhesion layer 34. The thickness of the adhesion layer 51 may be, for example, approximately 15 nm to 50 nm. The adhesion layer 51 may be, for example, a sputtering film. A portion of the adhesion layer 34 that covers the upper surface of the metal layer 33 is greater in thickness than a portion of the adhesion layer 51 that covers the upper surface of the insulation layer 40. In an example, the thickness of the portion of the adhesion layer 34 that covers the upper surface of the metal layer 33 is greater than or equal to two times the thickness of the portion of the adhesion layer 51 that covers the upper surface of the insulation layer 40.

The metal film 52 covers a surface of the adhesion layer 51 facing the inside of the via hole 41, that is, the inner surface of the adhesion layer 51. The metal film 52 covers the entire inner surface of the adhesion layer 51 and the entire upper surface of the adhesion layer 51. In an example, the metal film 52 covers the entire inner surface of the wall cover 35 exposed from the adhesion layer 51.

The material of the metal film 52 may be, for example, copper or a copper alloy. The thickness of the metal film 52 is, for example, greater than the thickness of the adhesion layer 51. The thickness of the metal film 52 may be, for example, approximately 100 nm to 500 nm. The metal film 52 may be, for example, a sputtering film.

The wall cover 35 of the adhesion layer 34, the adhesion layer 51, and the metal film 52 form a seed layer S2.

The metal layer 53, for example, fills the via hole 41 on the inner side of the metal film 52. The material of the metal layer 53 may be, for example, copper or a copper alloy.

The metal layer 53 may be, for example, an electrolytic plating layer.

### Structure of the Wiring Layer 60

The wiring layer 60 includes the adhesion layer 51 formed on the upper surface of the insulation layer 40, the metal film 52 formed on the upper surface of the adhesion layer 51, and a metal layer 61 formed on the upper surface of the metal film 52.

The adhesion layer 51 covers the upper surface of the insulation layer 40 located around the via hole 41. The metal film 52 covers, for example, the entire upper surface of the adhesion layer 51 that covers the upper surface of the insulation layer 40.

The metal layer 61 is formed on the metal layer 53 and the metal film 52 formed on the upper surface of the insulation layer 40. The metal layer 61 is formed continuously and integrally with the metal layer 53. The material of the metal layer 61 may be, for example, copper or a copper alloy. The metal layer 61 may be, for example, an electrolytic plating layer.

The side surface of the metal layer 61 includes a rough surface 61R having, for example, a greater surface roughness than the upper surface of the metal layer 61. The surface roughness of the rough surface 61R may be, for example, expressed as surface roughness Ra having a value of approximately 80 nm to 130 nm.

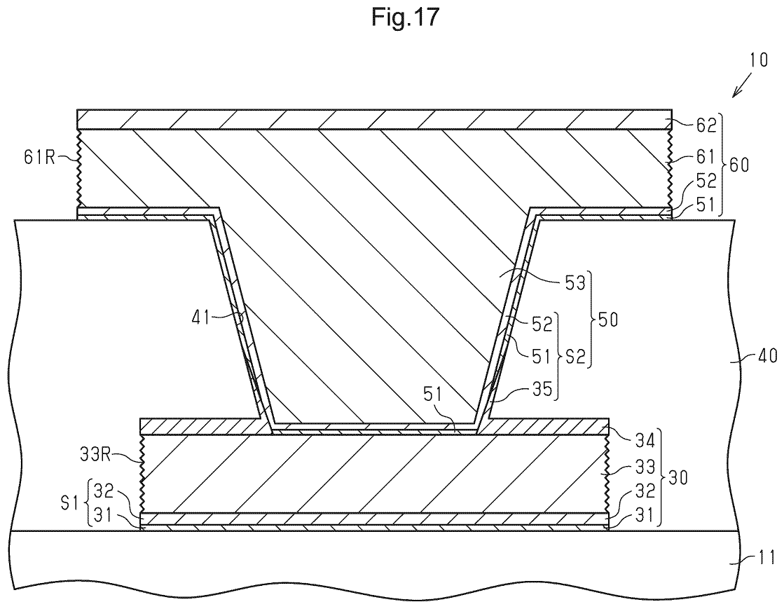

Although not illustrated in FIG. 2, an adhesion layer 62 (refer to FIG. 17) similar to the adhesion layer 34 is formed on the upper surface of the metal layer 61.

Although not illustrated in detail, the via wirings 72 and the wiring layer 80, illustrated in FIG. 1, have the same structure as the via wirings 50 and the wiring layer 60. Also, the via wirings 25 and the wiring layer 23 have the same structure as the via wirings 50 and the wiring layer 60.

The wiring substrate 10 may be inverted when used or may be arranged at any angle.

### Method for Manufacturing the Wiring Substrate 10

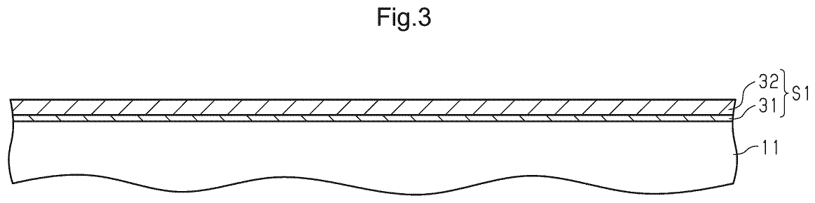

A method for manufacturing the wiring substrate 10 will now be described with reference to FIGS. 3 to 17. A method for manufacturing the structural body illustrated in FIG. 2, namely, the wiring layer 30, the insulation layer 40, the via hole 41, the via wiring 50, and the wiring layer 60, will be described in detail. To facilitate understanding, portions that ultimately become elements of the wiring substrate 10 are indicated by reference characters used to denote the final elements.

First, in the step illustrated in FIG. 3, the seed layer S1 is formed on the upper surface of the substrate body 11. For example, the adhesion layer 31 is formed to cover the entire upper surface of the substrate body 11, and then the metal film 32 is formed to cover the entire upper surface of the adhesion layer 31. The adhesion layer 31 and the metal film 32 may be formed by, for example, sputtering. In an example, titanium is sputtered and deposited on the upper surface of the substrate body 11 to form a Ti layer, or the adhesion layer 31. Then, copper is sputtered and deposited on the adhesion layer 31 to form a Cu layer, or the metal film 32. This forms the seed layer S1 having a double-layer structure (Ti layer/Cu layer).

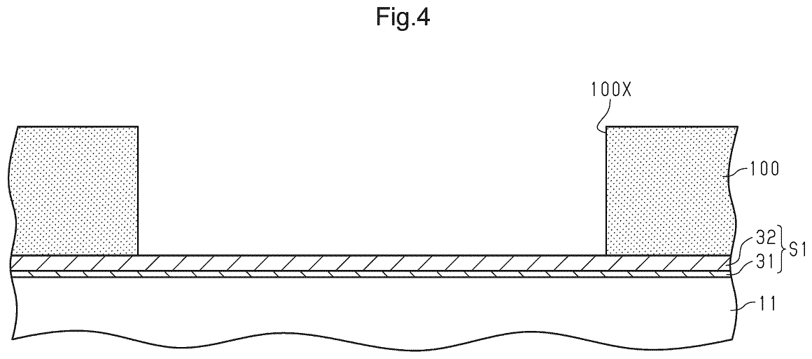

In the step illustrated in FIG. 4, a resist layer 100 having an opening pattern 100X at a given location is formed on the seed layer S1. The opening pattern 100X exposes a portion of the seed layer S1 corresponding to a region in which the metal layer 33 (refer to FIG. 2) is formed. For example, a material having resistance to the electrolytic plating process performed in the next step may be used as the material of the resist layer 100. For example, the material of the resist layer 100 may be a photosensitive dry film resist or a liquid photoresist (e.g., dry film resist or liquid resist of novolac-based resin or acrylic-based resin). In an example in which a photosensitive dry film resist is used, the upper surface of the seed layer S1 is laminated with a dry film by thermocompression bonding, and then the dry film is patterned by photolithography to form the resist layer 100 having the opening pattern 100X. When a liquid photoresist is used, the resist layer 100 may also be formed by the same steps.

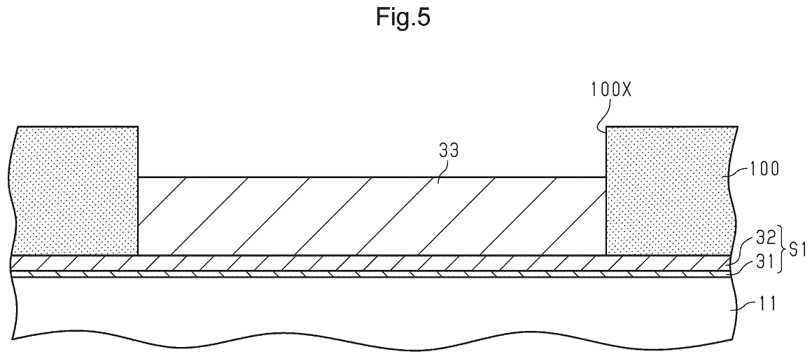

In the step illustrated in FIG. 5, electrolytic plating is performed on the seed layer S1 using the resist layer 100 as a plating mask and the seed layer S1 as a plating power feeding layer. That is, electrolytic plating (in this example, electrolytic Cu plating) is performed on the upper surface of the seed layer S1 exposed in the opening pattern 100X of the resist layer 100. The present step forms the metal layer 33 on the upper surface of the metal film 32 exposed from the opening pattern 100X.

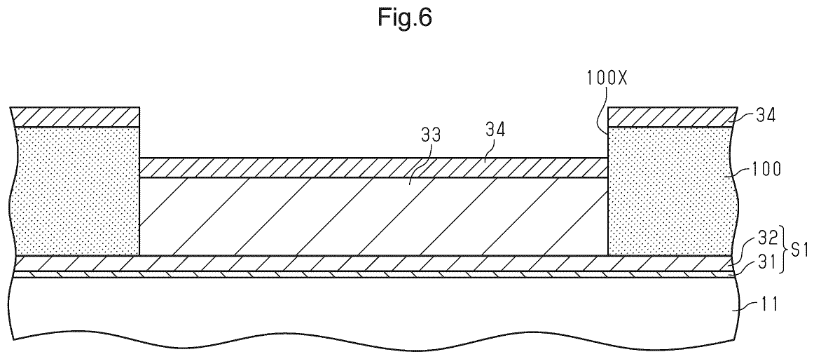

In the step illustrated in FIG. 6, the adhesion layer 34 is formed on the upper surface of the metal layer 33. The adhesion layer 34 may be formed by, for example, sputtering. In an example, titanium is sputtered and deposited on the upper surface of the metal layer 33 to form a Ti layer, or the adhesion layer 34. In this step, titanium is also deposited on the upper surface of the resist layer 100. Thus, a Ti layer is formed on the upper surface of the resist layer 100 as the adhesion layer 34. The adhesion layer 34 is greater in thickness than the adhesion layer 31. In an example, the thickness of the adhesion layer 34 is greater than or equal to two times the thickness of the adhesion layer 31.

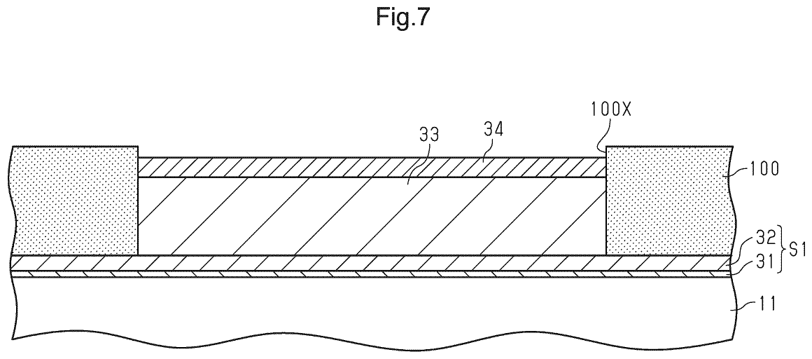

In the step illustrated in FIG. 7, the adhesion layer 34 is removed from the upper surface of the resist layer 100. In an example, the adhesion layer 34 is polished and removed from the upper surface of the resist layer 100 by chemical mechanical polishing (CMP).

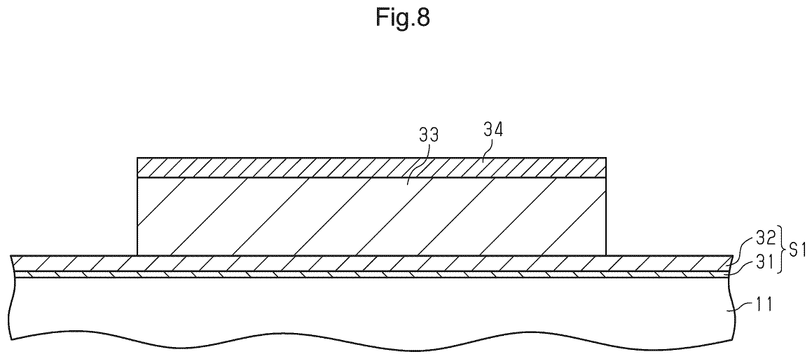

In the step illustrated in FIG. 8, the resist layer 100 illustrated in FIG. 7 is removed using an alkaline stripping solution (e.g., organic amine-based stripping solution, caustic soda, acetone, or ethanol). If the resist layer 100 is removable by this step without removing the adhesion layer 34 from the upper surface of the resist layer 100, the step illustrated in FIG. 7 may be omitted.

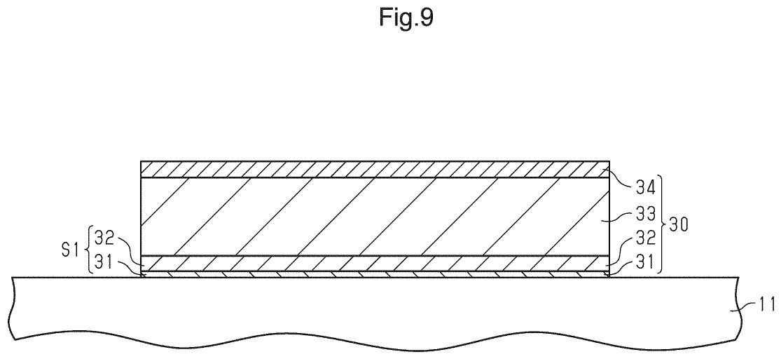

In the step illustrated in FIG. 9, as the metal layer 33 is used as an etching mask, unwanted portions of the seed layer S1, that is, the adhesion layer 31 and the metal film 32, are etched and removed. In this step, when the adhesion layer 31 is removed by etching, the adhesion layer 34, which is the same Ti layer as the adhesion layer 31, is partially removed together with the adhesion layer 31. Thus, in the present step, the thickness of the adhesion layer 34, or the Ti layer, is reduced from the upper surface. Since the adhesion layer 34 has a greater thickness than the adhesion layer 31, after removal of the unwanted adhesion layer 31, the adhesion layer 34 remains on the upper surface of the metal layer 33.

The manufacturing steps described above form the wiring layer 30 having a structure in which the adhesion layer 31, the metal film 32, the metal layer 33, and the adhesion layer 34 are sequentially stacked.

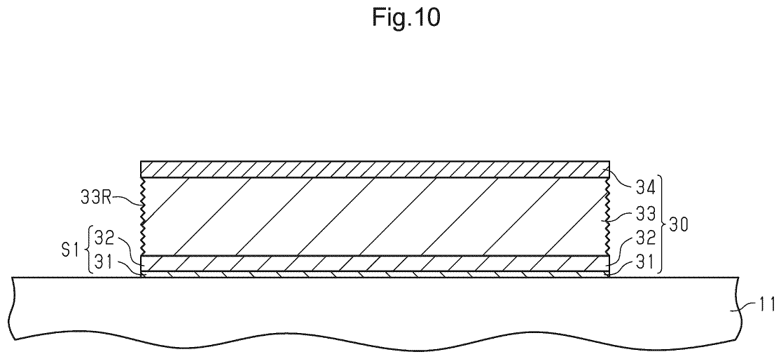

In the step illustrated in FIG. 10, a roughening process is performed on the wiring layer 30, in particular, the metal layer 33. As a result of the roughening process, the entirety of the side surfaces of the metal layer 33 that are exposed from the seed layer S1 and the adhesion layer 34 has the rough surface 33R. The lower surface of the metal layer 33, which is covered by the seed layer S1, and the upper surface of the metal layer 33, which is covered by the adhesion layer 34, are not roughened. Thus, the side surfaces of the metal layer 33 include the rough surface 33R, which has a greater surface roughness than the lower surface and the upper surface of the metal layer 33. The roughening process may be performed by, for example, blackening, etching, blasting, or the like.

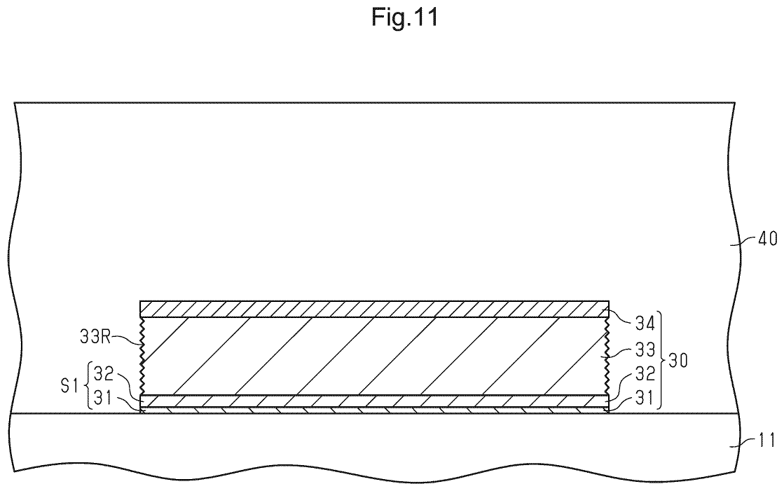

In the step illustrated in FIG. 11, the insulation layer 40 is formed on the upper surface of the substrate body 11 to cover the wiring layer 30. In an example, when a resin film is used as the insulation layer 40, the upper surface of the substrate body 11 is laminated with the resin film. The resin film is heated at a curing temperature or higher (e.g., approximately 130° C. to 200° C.) while being pressed so that the resin film is cured to form the insulation layer 40. The resin film may be, for example, a film of a thermosetting resin including an epoxy-based resin as a main component. When a liquid or paste of an insulating resin is used as the insulation layer 40, the liquid or paste of insulative resin is applied to the upper surface of the substrate body 11 through a spin coating process or the like. The applied insulating resin is heated at a curing temperature or higher so that the insulative resin is cured to form the insulation layer 40. The liquid or paste of insulating resin may be, for example, a thermosetting resin including an epoxy resin as a main component.

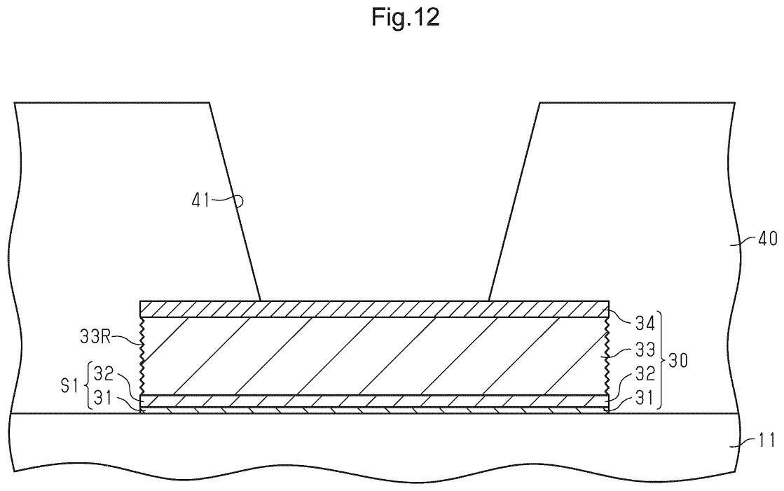

In the step illustrated in FIG. 12, the via hole 41 is formed in the insulation layer 40 on a given location so that the upper surface of the wiring layer 30 is partially exposed. The via hole 41 extends through the insulation layer 40 in the thickness-wise direction and expose a portion of the upper surface of the adhesion layer 34. The via hole 41 may be formed, for example, by laser drilling using a CO2 laser or a YAG laser.

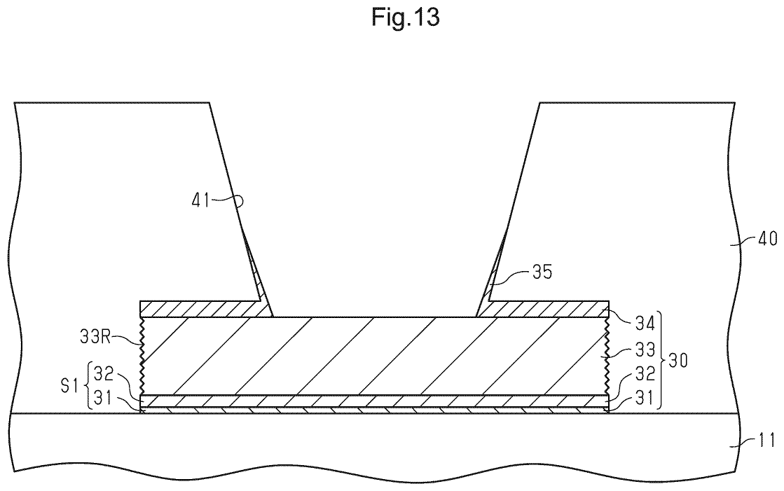

In the step illustrated in FIG. 13, re-sputtering is performed so that the adhesion layer 34 that is exposed at the bottom of the via hole 41 is re-sputtered and re-collected on the wall surface of the via hole 41 to form the wall cover 35 covering the wall surface of the via hole 41. The present step may be carried out, for example, by argon re-sputtering. In the present step, the adhesion layer 34 (Ti layer) exposed at the bottom of the via hole 41 is re-sputtered by argon (Ar) ions. Consequently, Ti deposits on the wall surface of the via hole 41 to form a Ti layer defining the wall cover 35. The adhesion layer 34, which is exposed at the bottom of the via hole 41, is greater in thickness than the adhesion layer 31. This allows a sufficient amount of metal to be re-sputtered and re-collected on the wall surface of the via hole 41. Thus, the wall cover 35 covering the lower end of the wall surface of the via hole 41 is appropriately formed. The thickness of the wall cover 35 increases from the upper end of the wall cover 35 toward the lower end of the via hole 41. In other words, in the present step, the processing condition of the re-sputtering is adjusted so that the wall cover 35 is formed to have a thickness that increases from the upper end of the wall cover 35 toward the lower end of the via hole 41. In addition, in the present step, the processing condition of the re-sputtering is adjusted so that the adhesion layer 34 that is exposed at the bottom of the via hole 41 is entirely re-sputtered to expose the upper surface of the metal layer 33. For example, when argon re-sputtering is performed, high-frequency power, pressure of argon (Ar) gas, and processing time are adjusted as the processing condition of the re-sputtering. In an example of the processing condition of the present step, high-frequency power is set to 500 W, the pressure of Ar gas is set to 0.5 Pa, and the processing time is set to 40 minutes.

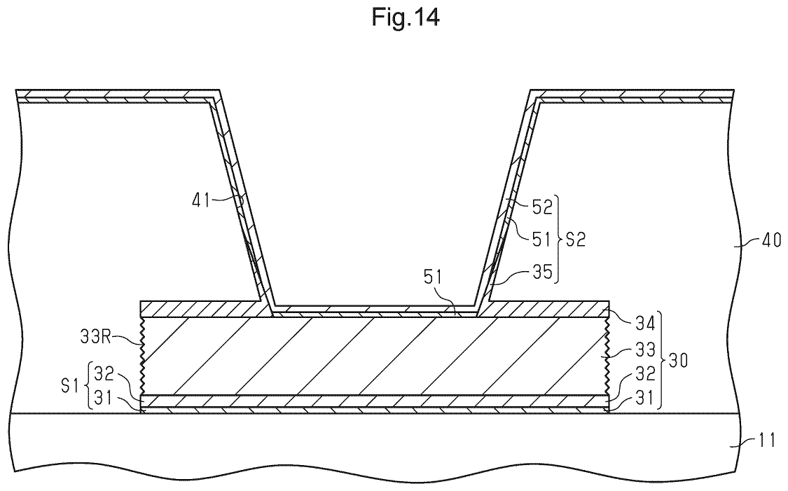

In the step illustrated in FIG. 14, the adhesion layer 51 is formed to cover the upper surface of the insulation layer 40 and the wall surface of the via hole 41. The adhesion layer 51 may be formed by, for example, sputtering. For example, Ti is sputtered so that Ti deposits on and covers the upper surface of the insulation layer 40 and the wall surface of the via hole 41. This forms a Ti layer defining the adhesion layer 51. In the present example, the adhesion layer 51 is formed to cover the entire upper surface of the insulation layer 40 and the entire bottom of the via hole 41, that is, the entire upper surface of the metal layer 33 exposed at the bottom of the via hole 41. Also, in the present example, the adhesion layer 51 covers the entire wall surface of the via hole 41 exposed from the wall cover 35. The adhesion layer 51 also covers the inner surface of the upper end of the wall cover 35 and exposes the inner surface of the lower end of the wall cover 35. Thus, the entire wall surface of the via hole 41 is appropriately covered by the adhesion layer 51 and the wall cover 35 of the adhesion layer 34.

Subsequently, the metal film 52 is formed to continuously cover the entire upper surface of the adhesion layer 51, the entire inner surface of the adhesion layer 51, and the entire inner surface of the wall cover 35. The metal film 52 may be formed by, for example, sputtering. For example, Cu is sputtered so that Cu deposits on and covers the upper surface and inner surface of the adhesion layer 51 and the inner surface of the wall cover 35. This forms a Cu layer defining the metal film 52.

As a result of the manufacturing steps described above, the seed layer S2 having the wall cover 35, the adhesion layer 51, and the metal film 52 is formed on the upper surface of the insulation layer 40 and the wall surface of the via hole 41.

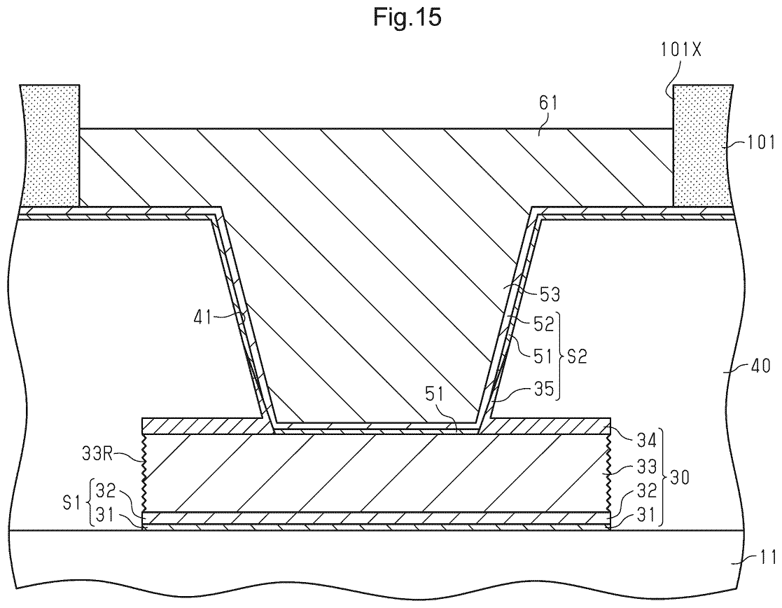

In the step illustrated in FIG. 15, in the same manner as the step illustrated in FIG. 4, a resist layer 101 having an opening pattern 101X at a given location is formed on the seed layer S2. The opening pattern 101X exposes a portion of the seed layer S2 corresponding to a region in which the metal layer 61 is formed.

Subsequently, in the same manner as the step illustrated in FIG. 5, electrolytic plating (in this example, electrolytic Cu plating) is performed on the seed layer S2 using the resist layer 101 as a plating mask and the seed layer S2 as a plating power feeding layer. The steps described above form the metal layer 53, which fills the via hole 41 on the inner side of the metal film 52 of the seed layer S2, and the metal layer 61, which is located in the opening pattern 101X.

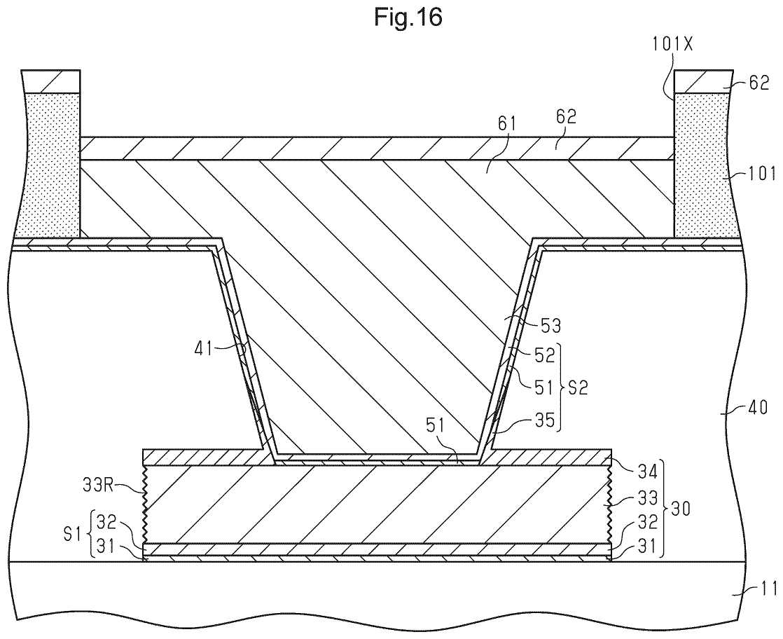

In the step illustrated in FIG. 16, in the same manner as the step illustrated in FIG. 6, the adhesion layer 62 is formed on the upper surface of the metal layer 61. Also, the adhesion layer 62 is formed on the upper surface of the resist layer 101. The material of the adhesion layer 62 may be, for example, Ti, TiN, TaN, Ta, Ni, Cr, a Cu—Ni alloy, or a Cu—Ni—Ti alloy. In the present embodiment, the adhesion layer 62 is a Ti layer. The adhesion layer 62 is greater in thickness than the adhesion layer 51. In an example, the adhesion layer 62 is greater in thickness than a portion of the adhesion layer 51 that covers the upper surface of the insulation layer 40.

In the step illustrated in FIG. 17, in the same manner as the steps illustrated in FIGS. 7 and 8, the adhesion layer 62 formed on the upper surface of the resist layer 101, and the resist layer 101 are removed. Subsequently, in the same manner as the step illustrated in FIG. 9, etching is performed to remove unwanted portions of the seed layer S2, that is, unwanted portions of the adhesion layer 51 and the metal film 52. Next, in the same manner as the step illustrated in FIG. 10, a roughening process is performed on the metal layer 61 to form the rough surface 61R on the side surface of the metal layer 61.

As a result of the manufacturing steps described above, the via wiring 50 including the wall cover 35, the adhesion layer 51, the metal film 52, and the metal layer 53 is formed in the via hole 41. In addition, the wiring layer 60 including the adhesion layer 51, the metal film 52, the metal layer 61, and the adhesion layer 62 is formed on the upper surface of the insulation layer 40.

Subsequently, in the same manner as the steps illustrated in FIGS. 11 to 15, the insulation layer 70, the via wirings 72, and the wiring layers 80 illustrated in FIG. 1 are formed. In the formation of the wiring layer 80, an adhesion layer similar to the adhesion layers 34 and 62 is not formed.

### Operation and Advantages of the First Embodiment

The first embodiment has the following operation and advantages.

(1-1) As the inclination angle of the wall surface of the via hole 41 becomes closer to 90 degrees, that is, the inclination angle becomes closer to an angle extending orthogonal to the upper surface of the metal layer 33, metal (in this example, Ti) is deposited less readily on the wall surface of the via hole 41 by normal sputtering. In particular, metal (in this example, Ti) does not readily deposit on the lower end of the wall surface of the via hole 41. When normal sputtering is performed so that only the adhesion layer 51 is formed on the wall surface of the via hole 41, collection of titanium is insufficient. As a result, the adhesion layer 51 is not formed on a portion of the wall surface of the via hole 41. The portion where the adhesion layer 51 is not formed appears, for example, at the lower end of the wall surface of the via hole 41 and an intermediate portion of the wall surface of the via hole 41. The portion where the adhesion layer 51 is not formed adversely affects the adhesion between the seed layer S2 and the insulation layer 40. As a result, cracks and voids may be formed in the via wiring 50 from the portion where the adhesion layer 51 is not formed. This may decrease the reliability of electrical connection between the via wiring 50 and the wiring layer 30.

In this regard, in the present embodiment, the adhesion layer 34 having a relatively large thickness is formed on the upper surface of the metal layer 33, and the insulation layer 40 is formed to cover the metal layer 33 and the adhesion layer 34. Then, re-sputtering is performed on the adhesion layer 34 exposed at the bottom of the via hole 41 in the insulation layer 40. When such re-sputtering is performed, the adhesion layer 34 (Ti layer) exposed at the bottom of the via hole 41 is re-sputtered by, for example, Ar ions. Consequently, Ti deposits on the wall surface of the via hole 41 to form a Ti layer defining the wall cover 35. If the adhesion layer 34 exposed at the bottom of the via hole 41 is thin and re-sputtering is performed, the amount of metal re-collected on the wall surface of the via hole 41 is insufficient. In this case, the wall cover 35 is not appropriately formed on the wall surface of the via hole 41.

In this regard, in the present embodiment, the adhesion layer 34 exposed at the bottom of the via hole 41 is greater in thickness than the adhesion layer 51. This allows a sufficient amount of metal to be re-collected on the wall surface of the via hole 41 when re-sputtering is performed. Thus, the re-sputtering appropriately forms the wall cover 35 covering the lower end of the wall surface of the via hole 41. As described above, the wall cover 35 is formed on a portion of the wall surface of the via hole 41 where the adhesion layer 51 is formed less readily. Thus, the entire wall surface of the via hole 41 is appropriately covered by the adhesion layer 51 and the wall cover 35 of the adhesion layer 34. Even when the inclination angle of the wall surface of the via hole 41 is close to 90 degrees, a situation in which the adhesion layers 34 and 51 are not formed on a portion of the wall surface of the via hole 41 is avoided effectively. This limits the adverse effect on the adhesion between the seed layer S2 and the insulation layer 40, thereby limiting formation of cracks and voids in the via wiring 50 effectively. As a result, the reliability of the electrical connection between the via wiring 50 and the wiring layer 30 is improved.

(1-2) The thickness of the adhesion layer 51 may be increased so that the entire wall surface of the via hole 41 is covered by only the adhesion layer 51. In this structure, the thickness of the adhesion layer 51 formed on the upper surface of the insulation layer 40 is also increased. In this case, in the step illustrated in FIG. 17, when etching is performed to remove an unwanted portion of the adhesion layer 51, the process time of the etching is increased. Accordingly, a relatively large undercut is formed in the wiring layer 60.

In this regard, in the present embodiment, the wall cover 35 of the adhesion layer 34 is formed. Thus, the entire wall surface of the via hole 41 is appropriately covered by the adhesion layer 51 and the wall cover 35 of the adhesion layer 34 without increasing the thickness of the adhesion layer 51. Therefore, in the step illustrated in FIG. 17, when etching is performed to remove an unwanted portion of the adhesion layer 51, the process time is shortened. Accordingly, a relatively small undercut is formed in the wiring layer 60.

(1-3) The thickness of the wall cover 35 decreases from the lower end of the wall surface of the via hole 41 toward the upper surface of the insulation layer 40. In other words, the thickness of the wall cover 35 increases from the upper end of the wall cover 35 toward the lower end of the wall surface of the via hole 41. Thus, the wall cover 35 has a relatively large thickness on the lower end of the wall surface of the via hole 41, that is, a portion of the wall surface of the via hole 41 where the adhesion layer 51 is formed less readily. Accordingly, a situation in which the adhesion layers 34 and 51 are not formed on a portion of the wall surface of the via hole 41 is avoided effectively.

(1-4) The upper surface of the metal layer 33 of the wiring layer 30 is exposed at the bottom of the via hole 41. In other words, the re-sputtering is performed so that the adhesion layer 34 does not remain at the bottom of the via hole 41. With this structure, the thickness of the adhesion layer (in this example, the adhesion layer 51) arranged between the metal layer 33 and the metal film 52 decreases as compared to a structure in which the adhesion layer 34 remains at the bottom of the via hole 41. This improves the adhesion between the metal layer 33, the metal film 52, and the metal layer 53, each of which is a Cu layer, as compared to a structure in which the adhesion layer 34 remains at the bottom of the via hole 41.

### Test Results

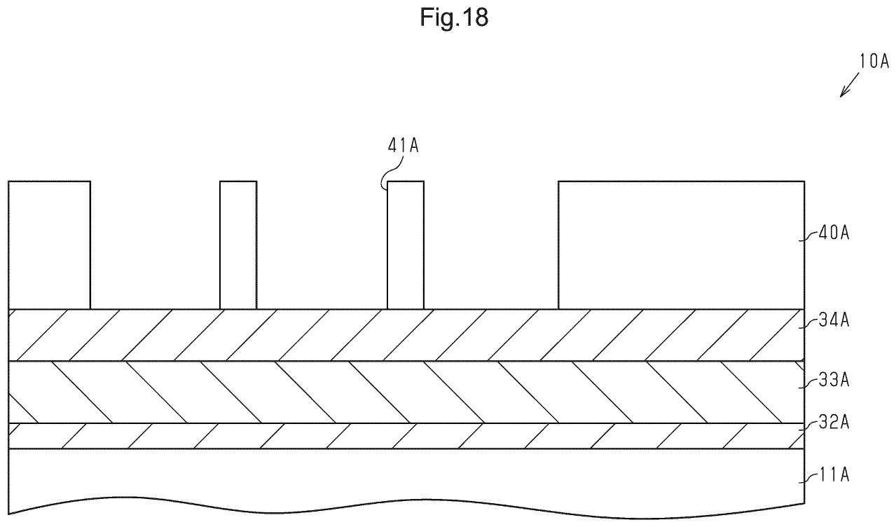

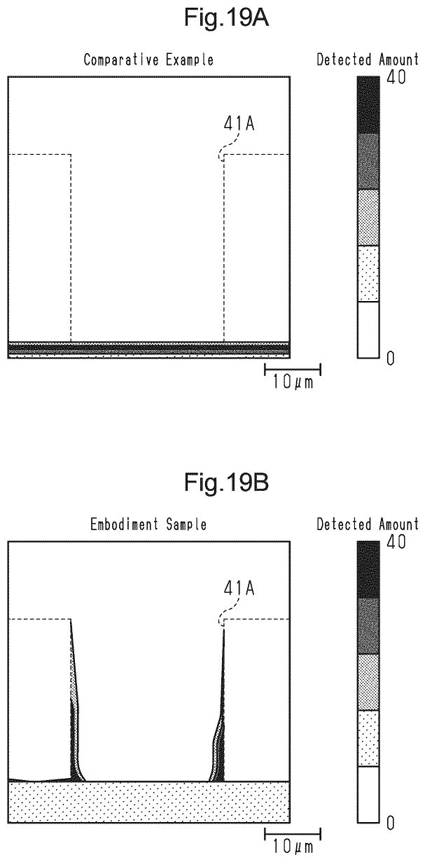

The test results will be described with reference to FIGS. 18, 19A, and 19B to confirm that when the adhesion layer 34 having a relatively large thickness is formed on the upper surface of the metal layer 33 and re-sputtering is performed, the adhesion layer 34 is appropriately re-collected on the wall surface of the via hole 41.

First, a structural body 10A illustrated in FIG. 18 is manufactured. In an example of the structural body, a copper foil 32A is formed on the upper surface of a core substrate 11A having a thickness of 1.2 mm. Then, an electrolytic Cu plating layer 33A having a thickness of 8 μm is formed on the upper surface of the copper foil 32A by an electrolytic Cu plating process. Next, an adhesion layer 34A having a thickness of 30 nm is formed on the upper surface of the electrolytic Cu plating layer 33A by sputtering. The adhesion layer 34A is a Ti layer. Subsequently, an insulation layer 40A having a via hole 41A is formed on the upper surface of the adhesion layer 34A. The thickness of the insulation layer 40A is 40 μm, and the diameter of the via hole 41A is 30 μm. The wall surface of the via hole 41A extends orthogonal to the upper surface of the adhesion layer 34A.

An embodiment sample is a structural body 10A on which re-sputtering is performed. A comparative example is a structural body 10A on which re-sputtering is not performed. The re-sputtering is argon re-sputtering with the setting of high-frequency power to 500 W, the pressure of Ar gas to 0.5 Pa, and the processing time to 40 minutes.

The embodiment sample and the comparative sample were analyzed by an electron probe micro analyzer (EPMA).

FIG. 19A illustrates the analysis result of titanium in the comparative sample. FIG. 19B illustrates the analysis result of titanium in the embodiment sample.

As illustrated in FIG. 19A, in the comparative sample, which does not undergo re-sputtering, titanium is not present on the wall surface of the via hole 41A. In contrast, as illustrated in FIG. 19B, in the embodiment sample, on which re-sputtering is performed, titanium is present on the wall surface of the via hole 41A. For example, titanium was detected from the lower end of the wall surface of the via hole 41A to the upper end of the wall surface of the via hole 41A. In particular, a relatively large amount of titanium was detected from the lower end of the wall surface of the via hole 41A. The test results indicate that in the embodiment sample, titanium appropriately collects on the lower end of the wall surface of the via hole 41A, where titanium does not readily collect. The test results also indicate that titanium appropriately collects on the wall surface of the via hole 41A even when the wall surface of the via hole 41A extends orthogonal to the upper surface of the adhesion layer 34A, that is, when Ti does not readily collect by particularly performing normal sputtering.

As described above, when the adhesion layer 34 having a relatively large thickness is formed on the upper surface of the metal layer 33 and re-sputtering is performed, titanium appropriately collects on the wall surface of the via hole 41. Accordingly, the wall cover 35 is appropriately formed on the wall surface of the via hole 41. The combination of the wall cover 35 (adhesion layer 34), which is formed by re-sputtering, and the adhesion layer 51, which is formed by normal sputtering, allows the entire wall surface of the via hole 41 to be appropriately covered by the adhesion layers 34 and 51.

### SECOND EMBODIMENT

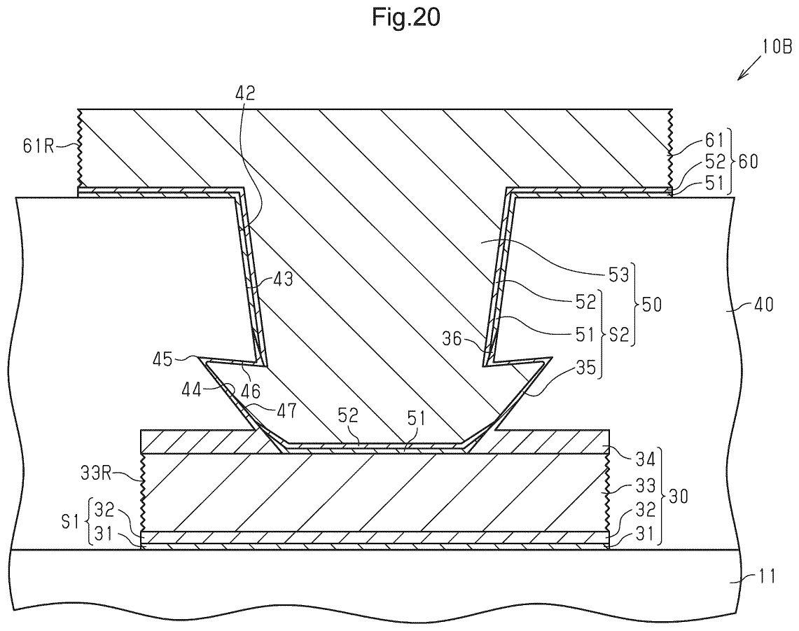

A second embodiment will now be described with reference to FIGS. 20 to 25. The present embodiment of a wiring substrate 10B differs from the first embodiment in the structure of the via hole. The differences from the first embodiment will be mainly discussed. The same reference numerals are given to those components that are the same as the corresponding components illustrated in FIGS. 1 to 19B. Such components will not be described in detail. FIG. 20 is a portion of a wiring substrate 10B obtained by enlarging a structural body in the range similar to that illustrated in FIG. 2.

As illustrated in FIG. 20, in the wiring substrate 10B of the present embodiment, the insulation layer 40 has a via hole 42 extending through the insulation layer 40 in the thickness-wise direction to expose a portion of the upper surface of the wiring layer 30. The via hole 42 may have any planar shape and any planar size. In the present embodiment, the via hole 42 is circular in plan view. The depth of the via hole 42 may be, for example, approximately 10 μm to 30 μm. The diameter of the via hole 42 may be, for example, approximately 10 μm to 50 μm.

### Structure of Via Hole 42

The wall surface of the via hole 42 includes, for example, a first wall surface 43 extending downward from the upper surface of the insulation layer 40 and a recess 44 recessed from the first wall surface 43 toward an outer side of the via hole 42 (i.e., direction away from the center of the via hole 42 in plan view). The recess 44 is located, for example, at the bottom of the via hole 42.

In an example, the first wall surface 43 downwardly extends from the upper open end of the via hole 42 to the recess 44. The first wall surface 43 is, for example, inclined toward the center of the via hole 42 in plan view as the first wall surface 43 extends from the upper side (the side of the upper surface of the insulation layer 40) toward the lower side (the side of the recess 44) in FIG. 20. The first wall surface 43 does not necessarily have to be straight. The first wall surface 43 may be partially or entirely convex or concave. In the present example, the first wall surface 43 is inclined at a constant inclination angle.

The recess 44 is continuous with the lower end of the first wall surface 43. The recess 44 is formed so as to increase the opening width (in the present example, diameter) of the via hole 42. The recess 44, for example, increases the opening width of the via hole 42 as compared to that at the lower end of the first wall surface 43. The recess 44 is formed so that the first wall surface 43 of the via hole 42 is recessed to the inside of the insulation layer 40. In other words, the recess 44 extends from the first wall surface 43 into the insulation layer 40. The recess 44 is formed, for example, continuously along the entire perimeter of the via hole 42.

The recess 44 includes an outer end 45, which is the most recessed part of the recess 44, a second wall surface 46 extending from the lower end of the first wall surface 43 to the outer end 45, and a third wall surface 47 extending from the outer end 45 to the upper surface of the wiring layer 30.

The outer end 45 is, for example, located farthest in plan view from the lower end of the first wall surface 43 in the recess 44. In the present embodiment, the outer end 45 is located upward from the lower end of the first wall surface 43. Thus, in the present embodiment, the recess 44 extends upward from the first wall surface 43 into the insulation layer 40.

The opening width (in this example, diameter) of the via hole 42 at the outer end 45 is set to be larger than the opening width (in this example, diameter) of the via hole 42 at the lower end of the first wall surface 43. The opening width of the via hole 42 at the outer end 45 is, for example, set to be greater than or equal to the width (in this example, diameter) of the upper open end of the via hole 42. In the present example, the opening width of the via hole 42 at the outer end 45 is set to be greater than the diameter of the upper open end of the via hole 42. In other words, in the present example, the outer end 45 is located in the insulation layer 40 farther inward from the upper open end of the via hole 42. In other words, in the present example, in plan view, the outer end 45 is located farther from the center of the via hole 42 than the upper open end of the via hole 42.

The second wall surface 46 extends from the lower end of the first wall surface 43 to the outer end 45 toward an outer side of the via hole 42. The second wall surface 46 is, for example, inclined upward from the lower end of the first wall surface 43 toward the outer end 45. The second wall surface 46 does not have to be straight. The second wall surface 46 may be partially or entirely convex or concave. In the present example, the second wall surface 46 is inclined at a constant inclination angle.

The third wall surface 47 extends downward from the outer end 45. The third wall surface 47 is, for example, inclined toward an inward part of the via hole 42 (i.e., toward the center of the via hole 42 in plan view) as the third wall surface 47 extends from the outer end 45 toward the upper surface of the wiring layer 30. The third wall surface 47 does not have to be straight. The third wall surface 47 may be partially or entirely convex or concave. In the present example, the third wall surface 47 is inclined at a constant inclination angle.

The lower end of the third wall surface 47 is, for example, located closest to the center of the via hole 42 in the third wall surface 47 in plan view. In plan view, the lower end of the third wall surface 47 is, for example, located at the same position as the lower end of the first wall surface 43 or located closer to the center of the via hole 42 than the lower end of the first wall surface 43 is.

As described above, the first wall surface 43, the second wall surface 46, the outer end 45, and the third wall surface 47 are continuously arranged to form the wall surface of the via hole 42. The first wall surface 43, the second wall surface 46, and the third wall surface 47 form a step at the bottom of the via hole 42.

### Structure of the Adhesion Layer 34

The adhesion layer 34 covers the upper surface of the metal layer 33. In an example, the adhesion layer 34 covers the entire upper surface of the metal layer 33 located at a position that does not overlap the bottom of the via holes 42 in plan view. In an example, the adhesion layer 34 exposes the upper surface of the metal layer 33 that overlaps the bottom of the via hole 42 in plan view. The thickness of the adhesion layer 34 is greater than the thickness of each of the adhesion layers 31 and 51. The thickness of the adhesion layer 34 may be, for example, approximately 50 nm to 150 nm.

The adhesion layer 34 includes a wall cover 35 covering the wall surface of at least a lower part of the via hole 42. The wall cover 35 covers, for example, the third wall surface 47, the outer end 45, and the second wall surface 46 of the recess 44 and covers a lower part of the first wall surface 43. The wall cover 35 exposes, for example, the wall surface of the upper part of the via hole 42, that is, the upper part of the first wall surface 43. In an example, the wall cover 35 continuously covers the third wall surface 47, the outer end 45, the second wall surface 46, and the lower part of the first wall surface 43. In an example, the wall cover 35 is formed continuously and integrally with the portion of the adhesion layer 34 that covers the upper surface of the metal layer 33. The wall cover 35 extends upward from the lower end of the wall surface of the via hole 42 along the third wall surface 47. The rising edge of the wall cover 35, that is, the lower end of the wall cover 35, is located, for example, closer to the center of the via hole 42 in plan view than the lower end of the first wall surface 43 is.

The wall cover 35 covers the entirety of the third wall surface 47. The thickness of the wall cover 35, for example, increases toward the lower end of the third wall surface 47. In other words, the thickness of the wall cover 35, for example, decreases toward the outer end 45. However, the portion of the wall cover 35 that covers the outer end 45 is, for example, greater in thickness than the portion of the wall cover 35 that covers the upper portion of the third wall surface 47. The wall cover 35 covers the entirety of the second wall surface 46. Thus, the wall cover 35 covers the entire wall surface of the recess 44.

The wall cover 35 extends upward from the lower end of the first wall surface 43. In the following description, the first wall surface 43 of the wall cover 35 may be referred to as a wall cover 36. The wall cover 36 is formed continuously and integrally with the wall cover 35 covering the second wall surface 46. The thickness of the wall cover 36 decreases from the lower end of the first wall surface 43 toward the upper surface of the insulation layer 40.

The thickness of the wall cover 35 is smaller than the thickness of the portion of the adhesion layer 34 that covers the upper surface of the metal layer 33. In an example, the thickness of a portion of the wall cover 35 that covers the lower end of the third wall surface 47 of the via hole 42 is less than or equal to one-half of the thickness of the portion of the adhesion layer 34 that covers the upper surface of the metal layer 33. The wall cover 35 is, for example, formed by re-sputtering to re-collect a portion of the adhesion layer 34 on the wall surface of the via hole 42.

### Structure of the Via Wiring 50

Each via wiring 50 includes, for example, the wall cover 35 of the adhesion layer 34, the adhesion layer 51 formed on the wall surface of the via hole 42 to cover the wall cover 35, the metal film 52 covering the adhesion layer 51, and the metal layer 53 formed in the via hole 42 on the inner side of the metal film 52.

In an example, the adhesion layer 51 covers a portion of the inner surface of the wall cover 35 and exposes the remaining portion of the inner surface of the wall cover 35. In the present embodiment, the adhesion layer 51 covers the inner surface of the upper end of the wall cover 36 and exposes the inner surface of the lower end of the wall cover 36. Thus, in the present embodiment of the first wall surface 43, the wall cover 36, which is part of the adhesion layer 34, partially overlaps the adhesion layer 51.

In an example, the adhesion layer 51 covers the inner surface of the rising edge of the wall cover 35 covering the recess 44 (i.e., the lower end of the wall cover 35) and exposes the remaining portion of the inner surface of the wall cover 35 covering the recess 44. In an example, the adhesion layer 51 covers the rising edge of the wall cover 35 that is located closer to the center of the via hole 42 in plan view than the lower end of the wall cover 36. The thickness of the adhesion layer 51 covering the rising edge of the wall cover 35, for example, increases toward the upper surface of the metal layer 33. In the present example, the adhesion layer 51 exposes most of the inner surface of the wall cover 35 formed on the wall surface of the recess 44. For example, in the present example, the adhesion layer 51 exposes the inner surface of the wall cover 35 covering the upper portion of the third wall surface 47, the inner surface of the wall cover 35 covering the outer end 45, and the inner surface of the wall cover 35 covering the second wall surface 46.

In an example, the adhesion layer 51 covers the entire upper surface of the metal layer 33 exposed at the bottom of the via hole 42. The adhesion layer 51 that covers the upper surface of the metal layer 33 is formed continuously and integrally with the adhesion layer 51 that covers the inner surface of the rising edge of the wall cover 35.

The adhesion layer 51 covers, for example, the entire wall surface of the via hole 42 exposed from the wall cover 35, that is, the entire surface of the first wall surface 43 exposed from the wall cover 35. The adhesion layer 51 continuously covers the wall surface of the via hole 42 and the upper surface of the insulation layer 40.

In the present embodiment, the adhesion layer 51 is separated into a portion covering the upper surface of the metal layer 33 and a portion covering the wall cover 35 formed on the first wall surface 43.

The metal film 52 covers, for example, the entire inner surface of the adhesion layer 51 and the entire upper surface of the adhesion layer 51. The metal film 52 covers, for example, a portion of the inner surface of the wall cover 35 exposed from the adhesion layer 51 and exposes the remaining portion of the inner surface of the wall cover 35 exposed from the adhesion layer 51. In an example, the metal film 52 covers the entire inner surface of the wall cover 36 exposed from the adhesion layer 51.

The wall cover 35 of the adhesion layer 34, the adhesion layer 51, and the metal film 52 form a seed layer S2.

The metal layer 53 fills, for example, the via hole 42 on the inner side of the metal film 52 and the wall cover 35.

As described above, the via wiring 50 fills the via hole 42 including the recess 44.

### Structure of the Wiring Layer 60

The wiring layer 60 includes the adhesion layer 51 formed on the upper surface of the insulation layer 40, the metal film 52 formed on the upper surface of the adhesion layer 51, and a metal layer 61 formed on the upper surface of the metal film 52.

### Method for Manufacturing the Wiring Substrate 10B

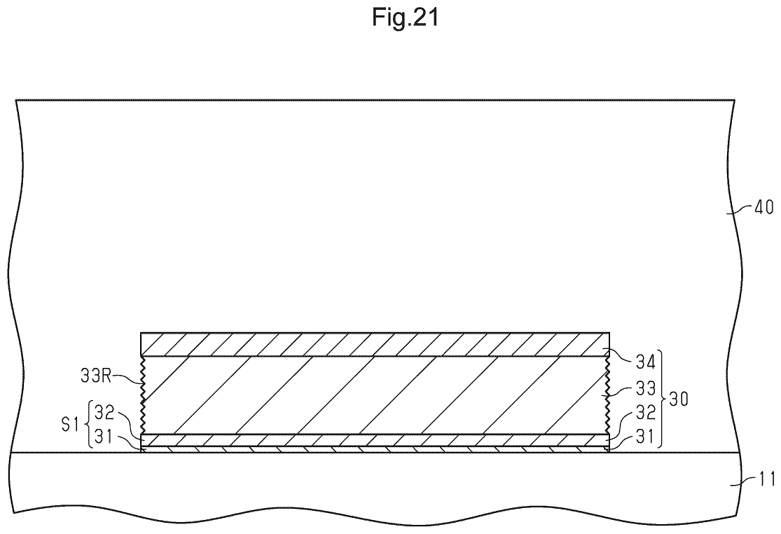

A method for manufacturing the wiring substrate 10B will now be described with reference to FIGS. 21 to 25. A method for manufacturing the structural body illustrated in FIG. 20, namely, the wiring layer 30, the insulation layer 40, the via hole 42, the via wiring 50, and the wiring layer 60, will be described in detail. To facilitate understanding, portions that will consequently become elements of the wiring substrate 10B are given the same reference characters as the final elements.

In the step illustrated in FIG. 21, steps similar to those illustrated in FIGS. 3 to 11 are performed to form the structural body illustrated in FIG. 21. In the structural body, the wiring layer 30, which includes the seed layer S1, the metal layer 33, and the adhesion layer 34, and the insulation layer 40, which covers the wiring layer 30, are sequentially stacked on the upper surface of the substrate body 11.

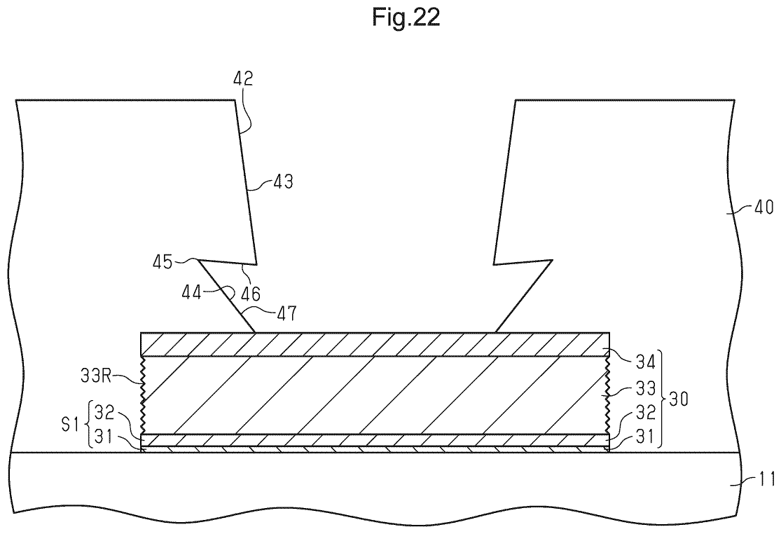

In the step illustrated in FIG. 22, the via hole 42 is formed in the insulation layer 40 on a given location so that the upper surface of the wiring layer 30 is partially exposed. The via hole 42 extends through the insulation layer 40 in the thickness-wise direction and exposes a portion of the upper surface of the adhesion layer 34. In the present example of the via hole 42, the recess 44 is formed at the bottom of the via hole 42. The via hole 42 having such a structure may be formed, for example, by adjusting processing conditions of laser drilling. For example, in the present step, the number of shots of the laser drilling is set to be greater than when a normal via hole (e.g., the via hole 41 illustrated in FIG. 2), which does not have the recess 44, is formed. For example, in the present step, the number of shots of the laser drilling is set to approximately 1.2 times to 2 times the number of shots performed to form a normal via hole having no recess 44.

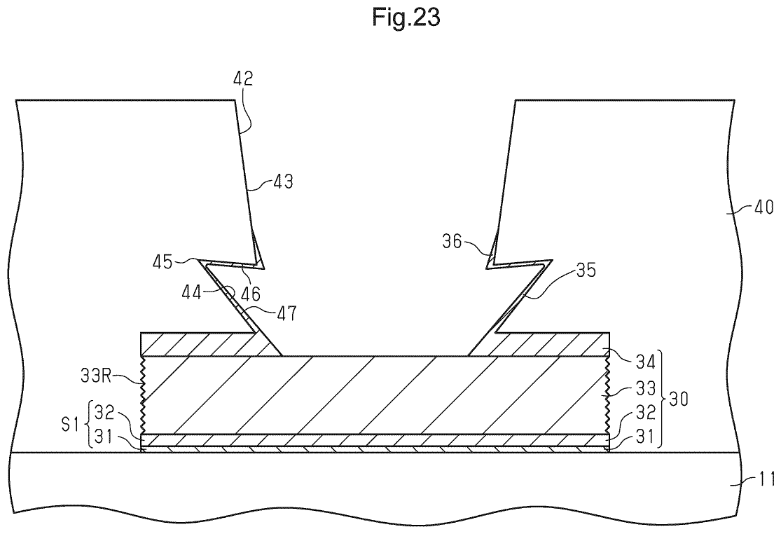

In the step illustrated in FIG. 23, in the same manner as the step illustrated in FIG. 13, re-sputtering is performed. The adhesion layer 34 that is exposed at the bottom of the via hole 42 is re-sputtered and re-collected on the wall surface of the via hole 42 to form the wall cover 35 covering the wall surface of the via hole 42. The present step may be carried out, for example, by argon re-sputtering. In this step, the wall cover 35 covers the entire wall surface of the recess 44 of the via hole 42 and the lower end of the first wall surface 43. The adhesion layer 34, which is exposed at the bottom of the via hole 42, is greater in thickness than the adhesion layer 31. This allows a sufficient amount of metal to be re-sputtered and re-collected on the wall surface of the recess 44. Thus, the entire wall surface of the recess 44, namely, the entire third wall surface 47, the outer end 45, and the entire second wall surface 46, are covered by the wall cover 35 in a preferred manner. In addition, in the present step, the processing condition of the re-sputtering is adjusted so that the adhesion layer 34 that is exposed at the bottom of the via hole 42 is entirely re-sputtered to expose the upper surface of the metal layer 33.

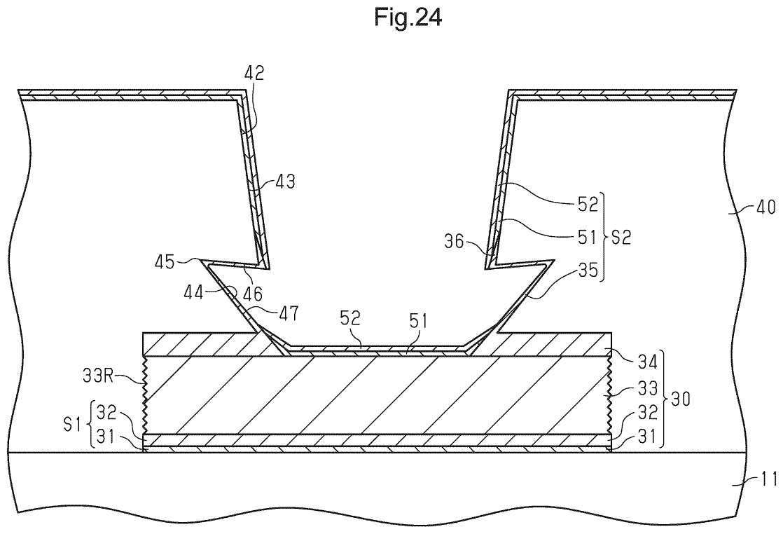

In the step illustrated in FIG. 24, in the same manner as the step illustrated in FIG. 14, the adhesion layer 51 is formed to cover the upper surface of the insulation layer 40 and the wall surface of the via hole 42 by, for example, sputtering. In the present embodiment, the adhesion layer 51 is formed to cover the entire upper surface of the insulation layer 40 and the entire upper surface of the metal layer 33 exposed at the bottom of the via hole 42. Also, in the present embodiment, the adhesion layer 51 is formed to cover the entire wall surface of the via hole 42 exposed from the wall cover 35 and a portion of the inner surface of the wall cover 35. Thus, the entire wall surface of the via hole 42 is appropriately covered by the adhesion layer 51 and the wall cover 35 of the adhesion layer 34.

Subsequently, the metal film 52 is formed to cover the entire upper surface of the adhesion layer 51 and the entire inner surface of the adhesion layer 51 by, for example, sputtering.

As a result of the manufacturing steps described above, the seed layer S2 having the wall cover 35, the adhesion layer 51, and the metal film 52 is formed on the upper surface of the insulation layer 40 and the wall surface of the via hole 42.

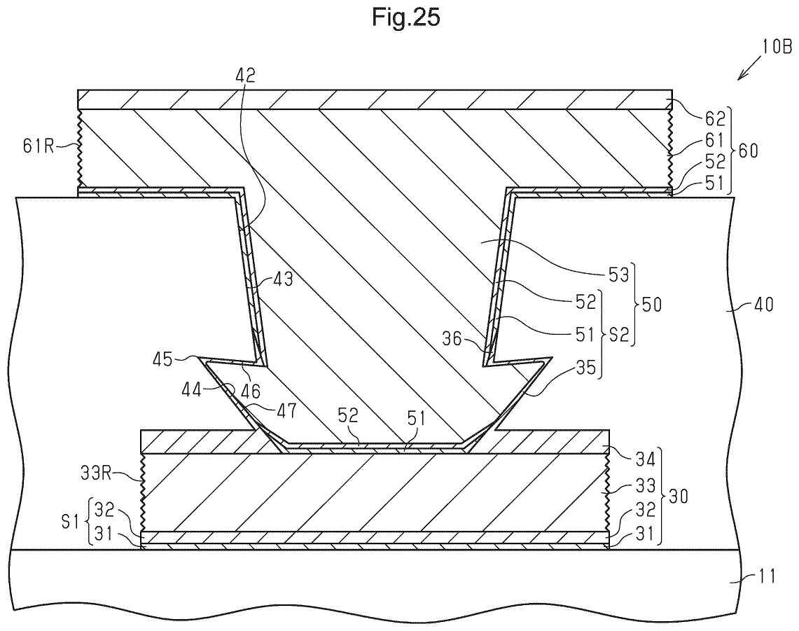

In the step illustrated in FIG. 25, in the same manner as the steps illustrated in FIGS. 15 to 17, the via wiring 50 including the wall cover 35, the adhesion layer 51, the metal film 52, and the metal layer 53 is formed in the via hole 42. In addition, the wiring layer 60 including the adhesion layer 51, the metal film 52, the metal layer 61, and the adhesion layer 62 is formed on the upper surface of the insulation layer 40.

### Operation and Advantages of the Second Embodiment

In addition to advantages (1-1) to (1-4) of the first embodiment, the present embodiment has the advantages described below.

(2-1) The wall surface of the via hole 42 includes the first wall surface 43, extending downward from the upper surface of the insulation layer 40, and the recess 44 recessed from the first wall surface 43 toward the outer side of the via hole 42. The wall cover 35, which is part of the adhesion layer 34, covers the entire wall surface of the recess 44. The recess 44 is filled with the via wiring 50 including the wall cover 35, the adhesion layer 51, the metal film 52, and the metal layer 53. As a result, a portion of the via wiring 50, that is, the portion of the via wiring 50 filling the recess 44, extends into the insulation layer 40. This produces the anchor effect, thereby improving the adhesion between the via wiring 50 and the insulation layer 40. As a result, separation of the via wiring 50 from the insulation layer 40 is limited effectively.

(2-2) When the via hole 42 has the recess 44, metal (in the present embodiment, Ti) is deposited less readily by normal sputtering on the wall surface of the recess 44. When normal sputtering is performed so that only the adhesion layer 51 is formed on the wall surface of the via hole 42, collection of titanium is insufficient. As a result, the adhesion layer 51 is not formed on a portion of the wall surface of the via hole 42. The portion where the adhesion layer 51 is not formed is present, for example, at the wall surface of the recess 44, in particular, in the vicinity of the outer end 45 of the recess 44. As described above, when the adhesion layer 51 is not formed on a portion of the inner surface of the recess 44, the metal layer 53 may not be formed in a portion of the via hole 42 including the recess 44.

In this regard, in the present embodiment, the adhesion layer 34 having a relatively large thickness is formed on the upper surface of the metal layer 33, and the insulation layer 40 is formed to cover the metal layer 33 and the adhesion layer 34. Then, re-sputtering is performed on the adhesion layer 34 exposed at the bottom of the via hole 42 in the insulation layer 40. When such re-sputtering is performed, the adhesion layer 34 (Ti layer) exposed at the bottom of the via hole 42 is re-sputtered by, for example, Ar ions. Consequently, Ti deposits on the wall surface of the via hole 42 to form a Ti layer defining the wall cover 35. The adhesion layer 34 exposed at the bottom of the via hole 41 is greater in thickness than the adhesion layer 51. This allows a sufficient amount of metal to be re-collected on the wall surface of the via hole 41 when re-sputtering is performed. Thus, the wall cover 35 covering the lower end of the wall surface of the via hole 42, for example, the entire wall surface of the recess 44, is appropriately formed by the re-sputtering. As described above, the wall cover 35 is formed on a portion of the wall surface of the via hole 42 where the adhesion layer 51 is formed less readily. The entire wall surface of the via hole 42 is appropriately covered by the adhesion layer 51 and the wall cover 35 of the adhesion layer 34. Thus, even when the via hole 42 has the recess 44, a situation in which the adhesion layers 34 and 51 are not formed on a portion of the wall surface of the via hole 42 is avoided effectively. This avoids a situation in which the metal layer 53 is not formed on a portion of the via hole 42 effectively. Accordingly, the via hole 42 having the recess 44 is appropriately filled with the via wiring 50.

(2-3) The wall cover 35 continuously covers the lower part of the first wall surface 43, the second wall surface 46, the outer end 45, and the third wall surface 47. The adhesion layer 51 covers the inner surface of the upper end of the wall cover 35 that covers the first wall surface 43 (i.e., the wall cover 36) and the first wall surface 43 exposed from the wall cover 35. In this structure, in the first wall surface 43, the adhesion layer 51 partially overlaps the wall cover 35, and the entire the first wall surface 43 exposed from the wall cover 35 is covered by the adhesion layer 51. Thus, the entirety of the first wall surface 43 is appropriately covered by the adhesion layer 51 and the wall cover 35, and the entire wall surface of the recess 44 is covered by the wall cover 35. Accordingly, the entire wall surface of the via hole 42 is appropriately covered by the adhesion layer 51 and the wall cover 35.

### Modified Examples

The embodiments described above may be modified as follows. The embodiments and the following modified examples may be combined as long as the combined modified examples remain technically consistent with each other.

The structure of the recess 44 in the second embodiment may be changed.

In the second embodiment, the second wall surface 46 of the recess 44 is inclined upward from the lower end of the first wall surface 43 toward the outer end 45. However, there is no limitation to such a structure. For example, the second wall surface 46 may be inclined downward from the lower end of the first wall surface 43 toward the outer end 45. For example, the second wall surface 46 may extend horizontally from the lower end of the first wall surface 43 toward the outer end 45.

In the second embodiment, the third wall surface 47 of the recess 44 is inclined toward an inward part of the via hole 42 as the third wall surface 47 extends from the outer end 45 toward the upper surface of the wiring layer 30. However, there is not limitation to such a structure. In an example, the third wall surface 47 may be inclined toward an outer side of the via hole 42 as the third wall surface 47 extends from the outer end 45 toward the upper surface of the wiring layer 30. In an example, the third wall surface 47 may extend vertically downward from the outer end 45.

In the second embodiment, the outer end 45 may be omitted from the recess 44. In this case, for example, the inner surface of the recess 44 may have a structure including only a second wall surface 46 that is inclined toward the outer side of the via hole 42 as the second wall surface 46 extends from the lower end of the first wall surface 43 toward the upper surface of the wiring layer 30.

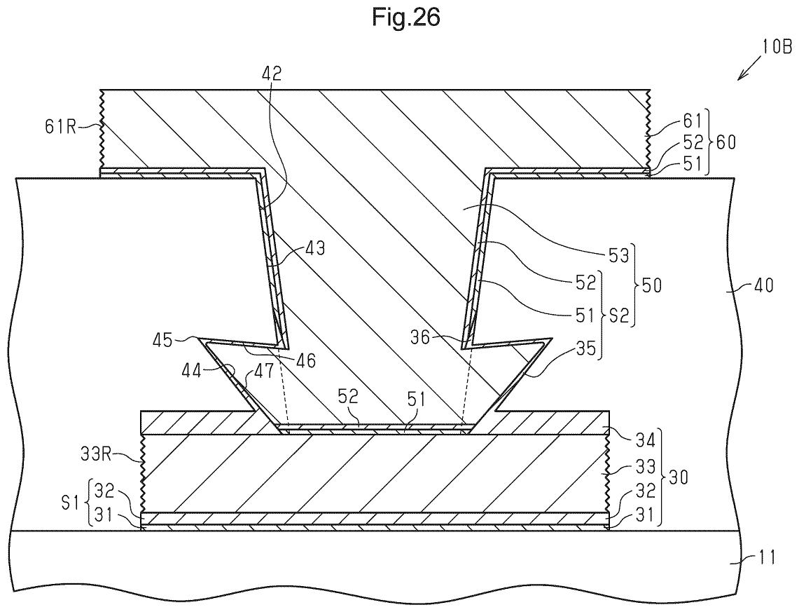

In an example, as illustrated in FIG. 26, in plan view the lower end of the third wall surface 47 may be located farther from the center of the via hole 42 than the lower end of the first wall surface 43 is. In other words, in plan view, the lower end of the third wall surface 47 may be located toward the outer side of the via hole 42 from the lower end of the first wall surface 43.

In an example, as illustrated in FIG. 26, in plan view the rising edge of the wall cover 35 may be located toward the outer side of the via hole 42 from an intersection of an extension line (broken line in the drawing) of the first wall surface 43 with the upper surface of the metal layer 33. In this case, for example, during the re-sputtering, the adhesion layer 34 that is located outward from the bottom of the via hole 42 toward the outer side of the via hole 42 is re-sputtered.

In an example, as illustrated in FIG. 26, the adhesion layer 51 that is formed at the bottom of the via hole 42 does not necessarily have to cover the rising edge of the wall cover 35 along the rising edge.

In the second embodiment, the wall cover 35 covers the lower part of the first wall surface 43. However, there is no limitation to such a structure. For example, the entirety of the first wall surface 43 may be exposed from the wall cover 35. In this case, the adhesion layer 51 covers the entirety of the first wall surface 43. The adhesion layer 51 covering the first wall surface 43 is joined to the wall cover 35 covering the entire wall surface of the recess 44.

In the embodiments, in the wiring layer 30, the upper surface of the metal layer 33 is partially exposed at the bottom of the via holes 41 and 42. However, there is no limit to such a structure. In other words, in the embodiments, the entirety of the adhesion layer 34 exposed at the bottom of the via holes 41 and 42 is re-sputtered so that the upper surface of the metal layer 33 is exposed. However, there is no limitation to such a structure.

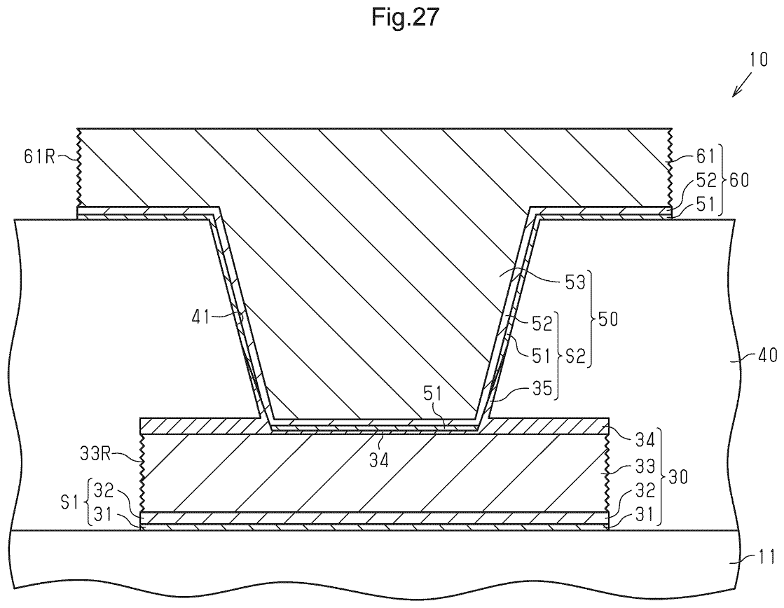

For example, as illustrated in FIG. 27, in the first embodiment the adhesion layer 34 may partially remain at the bottom of the via hole 41. In this case, a portion of the adhesion layer 34 that is exposed at the bottom of the via hole 41 is smaller in thickness than a portion of the adhesion layer 34 that covers the upper surface of the metal layer 33 and does not overlap the bottom of the via holes 41 in plan view. In an example, the thickness of the portion of the adhesion layer 34 exposed at the bottom of the via hole 41 is smaller than or equal to the thickness of a portion of the adhesion layer 51 that covers the upper surface of the insulation layer 40. In the same manner, in the second embodiment, the adhesion layer 34 may partially remain at the bottom of the via hole 42.

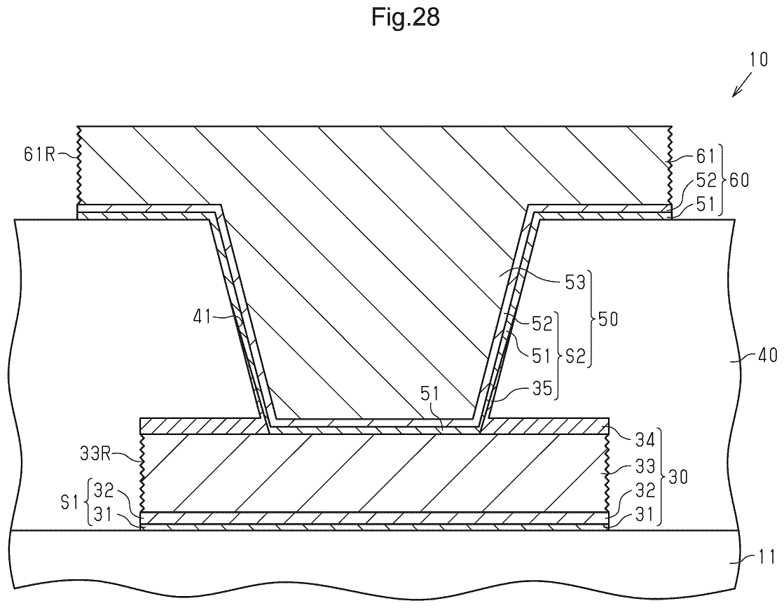

For example, as illustrated in FIG. 28, the adhesion layer 51 may cover the entire inner surface of the wall cover 35. In this case, the adhesion layer 51 continuously covers the upper surface of the wiring layer 30 exposed at the bottom of the via hole 41, the inner surface of the wall cover 35, the wall surface of the via hole 41 exposed from the wall cover 35, and the upper surface of the insulation layer 40.

In the embodiments, the wall cover 35 covers a portion of the wall surface of the via holes 41 and 42. However, there is no limitation to such a structure. For example, the wall cover 35 may cover the entire wall surface of the via holes 41 and 42.

In the embodiments, the adhesion layers 31, 34, 51, and 62 all include a Ti layer. However, there is no limitation to such a structure. For example, the adhesion layers 31, 34, 51, and 62 each may be formed from a different metal.

In the embodiments, each of the via wirings 25, 50, and 72 of the wiring substrates 10 and 10B has the same structure as the via wiring 50. However, there is no limitation to such a structure. For example, the via wirings 25 and 72 may differ in structure from the via wiring 50. For example, the structure corresponding to the wall cover 35 may be omitted. For example, of the via wirings 25, 50, and 72, only the via wiring 72 may have the same structure as the via wiring 50 illustrated in FIGS. 2 and 20.

In the embodiments, the structure of the wiring substrates 10 and 10B may be changed.

In the embodiments, in the wiring substrates 10 and 10B, the number of wiring layers, routing, and the number of insulation layers may be changed in various manners.

In the embodiments, the solder resist layer 24 may be omitted.

In embodiments, the solder resist layer 90 may be omitted.

### CLAUSES

This disclosure further encompasses the following embodiments.

1. A method for manufacturing a wiring substrate, the method including:
forming a first wiring layer that includes a first metal layer and a first adhesion layer covering an upper surface of the first metal layer;
forming a first insulation layer covering an upper surface of the first wiring layer and a side surface of the first wiring layer;
forming a via hole extending through the first insulation layer in a thickness-wise direction and exposing a portion of an upper surface of the first adhesion layer;
re-collecting the first adhesion layer exposed at a bottom of the via hole on a wall surface of the via hole to form a wall cover covering the wall surface of the via hole by performing re-sputtering; and
forming a via wiring filling the via hole and a second wiring layer integrally with the via wiring, the second wiring layer being formed on an upper surface of the first insulation layer, in which
the forming the via wiring and the second wiring layer includes:
   forming a second adhesion layer on the wall surface of the via hole to cover an inner surface of the wall cover;
   forming a first metal film covering the second adhesion layer; and
   forming a second metal layer filling the via hole on an inner side of the first metal film,
the second adhesion layer is formed to cover the upper surface of the first insulation layer, and
a portion of the first adhesion layer that covers the upper surface of the first metal layer is greater in thickness than a portion of the second adhesion layer that covers the upper surface of the first insulation layer.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a first wiring layer;
a first insulation layer covering an upper surface of the first wiring layer and a side surface of the first wiring layer;
a via hole extending through the first insulation layer in a thickness-wise direction and exposing a portion of the upper surface of the first wiring layer;
a via wiring filling the via hole; and
a second wiring layer formed integrally with the via wiring and stacked on an upper surface of the first insulation layer, wherein
the first wiring layer includes a first metal layer and a first adhesion layer formed on an upper surface of the first metal layer,
the first adhesion layer includes a wall cover covering a wall surface of at least a lower part of the via hole,
the via wiring includes
the wall cover,
a second adhesion layer formed on a wall surface of the via hole so as to cover an inner surface of the wall cover,
a first metal film covering the second adhesion layer, and
a second metal layer filling the via hole on an inner side of the first metal film,
the second adhesion layer covers the upper surface of the first insulation layer, and
a portion of the first adhesion layer that covers the upper surface of the first metal layer is greater in thickness than a portion of the second adhesion layer that covers the upper surface of the first insulation layer.

2. The wiring substrate according to claim 1, wherein the wall cover has a thickness that decreases from a lower end of the wall surface of the via hole toward the upper surface of the first insulation layer.

3. The wiring substrate according to claim 1, wherein the second adhesion layer covers the upper surface of the first wiring layer exposed at a bottom of the via hole and covers the wall surface of the via hole exposed from the wall cover.

4. The wiring substrate according to claim 3, wherein
the upper surface of the first metal layer of the first wiring layer is exposed at the bottom of the via hole, and
the second adhesion layer covers the upper surface of the first metal layer exposed at the bottom of the via hole.

5. The wiring substrate according to claim 3, wherein
an upper surface of the first adhesion layer of the first wiring layer is exposed at the bottom of the via hole,
the second adhesion layer covers the upper surface of the first adhesion layer exposed at the bottom of the via hole, and
a portion of the first adhesion layer that is exposed at the bottom of the via hole is smaller in thickness than a portion of the first adhesion layer that covers the upper surface of the first metal layer and does not overlap the bottom of the via hole in plan view.

6. The wiring substrate according to claim 1, wherein
the second adhesion layer exposes a portion of the inner surface of the wall cover, and
the first metal film covers entirety of an inner surface of the second adhesion layer and entirety of the inner surface of the wall cover exposed from the second adhesion layer.

7. The wiring substrate according to claim 3, wherein
the second adhesion layer covers entirety of the inner surface of the wall cover, and
the second adhesion layer continuously covers the upper surface of the first wiring layer exposed at the bottom of the via hole, the inner surface of the wall cover, the wall surface of the via hole exposed from the wall cover, and the upper surface of the first insulation layer.

8. The wiring substrate according to claim 1, wherein
the wall surface of the via hole includes a first wall surface extending downward from the upper surface of the first insulation layer and a recess recessed from the first wall surface to an outer side of the via hole,
the recess is formed at the bottom of the via hole,
the wall cover covers entirety of a wall surface of the recess, and
the via wiring fills the recess.

9. The wiring substrate according to claim 8, wherein
the recess includes a second wall surface extending from a lower end of the first wall surface toward the outer side of the via hole to an outer end of the recess, the outer end being a most recessed part of the recess, and a third wall surface extending from the outer end to the upper surface of the first wiring layer,
the wall cover covers at least a lower part of the first wall surface,
the wall cover continuously covers the first wall surface, the second wall surface, the outer end, and the third wall surface,
the second adhesion layer exposes a portion of the inner surface of the wall cover, and
the second adhesion layer covers the inner surface of the wall cover on at least an upper end part of a portion of the wall cover covering the first wall surface and also covers entirety of the first wall surface exposed from the wall cover, and
the first metal film covers entirety of an inner surface of the second adhesion layer and exposes a portion of the inner surface of the wall cover.

10. The wiring substrate according to claim 9, wherein
the second wall surface is inclined upward from the lower end of the first wall surface toward the outer end, and
the third wall surface is inclined toward an inner side of the via hole as the third wall surface extends from the outer end toward the upper surface of the first wiring layer.

11. The wiring substrate according to claim 1, wherein
the first wiring layer includes a third adhesion layer, a second metal film covering an upper surface of the third adhesion layer, the first metal layer covering an upper surface of the second metal film, and the first adhesion layer, and
a portion of the first adhesion layer that covers the upper surface of the first metal layer is greater in thickness than the third adhesion layer.

12. The wiring substrate according to claim 1, wherein
the second wiring layer includes the second adhesion layer covering the upper surface of the first insulation layer, the first metal film covering the upper surface of the second adhesion layer, a third metal layer formed on the upper surface of the first metal film, and a fourth adhesion layer formed on an upper surface of the third metal layer, and
a portion of the fourth adhesion layer that covers the upper surface of the third metal layer is greater in thickness than a portion of the second adhesion layer that covers the upper surface of the first insulation layer.

13. The wiring substrate according to claim 1, wherein
the wall cover of the first adhesion layer is formed continuously and integrally with the portion of the first adhesion layer that covers the upper surface of the first metal layer.

14. The wiring substrate according to claim 1, wherein
the wall cover of the first adhesion layer and the second adhesion layer directly cover the wall surface of the via hole while partially overlapping each other on the wall surface of the via hole.

15. The wiring substrate according to claim 1, wherein
the portion of the first adhesion layer that covers the upper surface of the first metal layer is greater in thickness than each of the wall cover and the second adhesion layer.

16. The wiring substrate according to claim 1, wherein
the via wiring includes a seed layer covering the wall surface of the via hole, and the second metal layer formed on the seed layer and filling the via hole,
the seed layer has a multilayer structure in which a combination of layers changes from an upper end of the wall surface of the via hole to a lower end of the wall surface of the via hole, wherein
at the upper end of the wall surface of the via hole, the seed layer has a two-layer structure comprising the first metal film and the second adhesion layer, and
at the lower end of the wall surface of the via hole, the seed layer has a two-layer or three-layer structure comprising the first metal film and at least one of the wall cover and the second adhesion layer.
